(19) United States
(12) Patent Application Publication
(10) Pub. No.: US 2024/0047531 A1
(43) Pub. Date: Feb. 8, 2024

(54) POWER DEVICES WITH IMPROVED ON-RESISTANCE

(71) Applicant: Purdue Research Foundation, West Lafayette, IN (US)

(72) Inventors: James Albert Cooper, Santa Fe, NM (US); Dallas Todd Morisette, Lafayette, IN (US)

(73) Assignee: Purdue Research Foundation, West Lafayette, IN (US)

(21) Appl. No.: 18/227,969

(22) Filed: Jul. 30, 2023

Related U.S. Application Data
(60) Provisional application No. 63/393,834, filed on Jul. 30, 2022.

(51) Int. Cl. H01L 29/10; H01L 29/78; H01L 29/739; H01L 29/74; H01L 29/423

(52) U.S. Cl. CPC H01L 29/1045; H01L 29/7802; H01L 29/7813; H01L 29/7816; H01L 29/7397; H01L 29/74; H01L 29/42364; H01L 29/1608

(57) ABSTRACT

A metal oxide semiconductor (MOS)-based power device includes a semiconductor region, drain and source electrodes, a gate electrode separated from the semiconductor region by SiO₂, where the channel length (CHL) has a range of between about 0.6 μm and about 0.5 μm, the silicon dioxide has a corresponding thickness (tₒₓ) range of between about 5 nm to about 30 nm, where the CHL has a range of between about 0.5 μm and about 0.4 μm, the tₒₓ has a corresponding range of between about 5 nm to about 25 nm, where the CHL has a range of between about 0.4 μm and about 0.3 μm, the tₒₓ has a corresponding range of between about 5 nm to about 20 nm, where the CHL has a range of between about 0.3 μm and about 0.2 μm, the tₒₓ has a corresponding range of between about 5 nm to about 15 nm.

### CROSS-REFERENCE TO RELATED APPLICATIONS

The present non-provisional patent application is related to and claims the priority benefit of U.S. Provisional Patent Application Ser. No. 63/393,834, entitled POWER DEVICES WITH IMPROVED ON-RESISTANCE which was filed Jul. 30, 2022, the contents of which are hereby incorporated by reference in its entirety into the present disclosure.

### STATEMENT REGARDING GOVERNMENT FUNDING

This invention was made with government support under DE-AR0001009 awarded by Advanced Research Projects Agency-Energy. The government has certain rights in the invention.

### TECHNICAL FIELD

The present disclosure generally relates to electronic switches, and in particular, to power devices with increased short circuit robustness.

### BACKGROUND

This section introduces aspects that may help facilitate a better understanding of the disclosure. Accordingly, these statements are to be read in this light and are not to be understood as admissions about what is or is not prior art.

Referring to FIG. 25, a schematic of an electronic switching system 10 is shown which includes an electronic switch, e.g., a power metal oxide semiconductor field effect transistor (MOSFET), 12 and a load 14. The load 14 is coupled to a source. The electronic switch 12, which includes a control terminal 16, a first terminal 18 and second terminal 20 is coupled to the load 14 and the ground. The control terminal 16 controls the electronic switch by essentially establishing a path for current to flow between the first terminal 18 and the second terminal 20.

The closing of the switch is shown to convey the concept. In actuality, when an appropriate voltage is applied to the control terminal 16, a channel is formed between the first and second terminals 18 and 20, thereby adaptable to pass the current there between. In the on state, the electronic switch 12 poses a resistance (identified as R_{ON}) 22 which when placed in series with a load resistance 24 in the load 14, establish the current (essentially, voltage of the source divided by the algebraic addition of the two resistances 22 and 24). Typically, the resistance of the resistor 22 is smaller than the resistance of the resistor 24. In case of a failure by the load 14, where the load is shorted (signified by the dotted line 26), a sudden rush of current passes through the electronic switch 12 which is essentially equal to the voltage of the source divided by the resistance of the resistor 22. This high level of current results in quick heating of the electronic switch 12 leading to its failure. The resistance of the resistor 22 plays a significant role in such heating. A low value of resistance (desired for normal operations, i.e., when the load is operating normally) can result in significantly higher current when the load is shorted; while too much resistance can result in negative results during normal operations.

Therefore, there is an unmet need for a novel power device arrangement that increases robustness of the power device to short circuit conditions concurrently improving the on-resistance without sacrificing the normal operational parameters, such as on resistance.

### SUMMARY

A metal oxide semiconductor (MOS)-based power device in 4H-SiC semiconductor is disclosed. The MOS-based power device includes a semiconductor region, a drain electrode and a source electrode, and a gate electrode separated from the semiconductor region by silicon dioxide as a dielectric material, wherein a load current passing through the drain and source electrodes is controlled by an electric field induced by the gate electrode into the semiconductor region thereby forming a conductive channel. If the channel length has a range of between about 0.6 μm and about 0.5 μm, the silicon dioxide has a corresponding thickness range of between about 5 nm to about 30 nm. If the channel length has a range of between about 0.5 μm and about 0.4 μm, the silicon dioxide has a corresponding thickness range of between about 5 nm to about 25 nm. If the channel length has a range of between about 0.4 μm and about 0.3 μm, the silicon dioxide has a corresponding thickness range of between about 5 nm to about 20 nm. If the channel length has a range of between about 0.3 μm and about 0.2 μm, the silicon dioxide has a corresponding thickness range of between about 5 nm to about 15 nm. The device is configured to withstand greater than 100 V between the source and the drain electrodes while carrying the load current.

### BRIEF DESCRIPTION OF DRAWINGS

FIG. 1 is a symbolic representation of a power device, e.g., a power metal oxide semiconductor field effect transistor (MOSFET).

FIG. 2 is a schematic of the MOSFET of FIG. 1 with a load.

FIG. 3 is a cross sectional view of a MOS power device, and in particular a double-diffused MOS field effect transistor (DMOSFET).

FIG. 4 is a cross sectional view of a superjunction DMOSFET.

FIG. 5 is a cross sectional view of a lateral DMOSFET.

FIG. 6 is a graph of drain current I_{D} of a MOSFET as a function of V_{DS} for a gate voltage greater than the threshold voltage V_{T}.

FIG. 7 is a graph of calculated current density vs. drain voltage curves for a 900 V SiC DMOSFET with gate oxide thicknesses varying from 5-50 nm (one graph for each of 5 nm, 15 nm, 30 nm, and 50 nm).

FIG. 8 is a graph of estimated increase in short circuit withstand time with this decrease in oxide thickness.

FIG. 9 is a cross sectional view of a UMOSFET.

FIG. 10 is a cross sectional view of a superjunction UMOSFET.

FIG. 11 is a graph of current density vs. drain voltage curves for a 900 V SiC DMOSFET with an SiO₂ gate dielectric and channel length of 0.5 μm calculated by two-dimensional numerical simulations with gate oxide thicknesses varying from 10-50 nm (one graph for each of 5 nm, 15 nm, 30 nm, and 50 nm) with channel length set to 0.5 μm.

FIG. 12 is another graph of current density vs. drain voltage curves where reducing the channel length from 0.5 μm to 0.2 μm increases the saturation current (thereby reducing short circuit withstand time), but with the benefit of reduced on-resistance (steeper slope near the origin, corresponding to the normal operating point A in FIG. 6).

FIG. 13 is a graph of channel resistance in mΩ cm² vs. channel length in μm vs. short circuit withstand time in μs.

FIG. 14 is a three-dimensional graph of channel length in μm vs. insulator thickness in nm vs. (V_{G}−V_{T}) in V demonstrating a safe operating volume in this three-dimensional parameter space.

FIG. 15 is schematic of a lateral power MOSFET device is provided that is used for simulation depicting various structures, with dimensions provided only as a non-limiting example.

FIG. 16 is graph of doping concentration vs. depth in μm in different regions of the device shown in FIG. 15.

FIG. 17 is a graph of blocking voltage in V vs. channel length for the doping profile of FIG. 16.

FIG. 18 is a graph of drain current in mA/μm (i.e., current per unit width of the MOSFET, where width is measured in μm) vs. drain voltage in V when the device is in the on state.

FIG. 19 is the linear region near the origin of FIG. 18, shown in greater detail.

FIG. 20 is a graph of the on-resistance in mΩ-cm² vs. channel length in μm for various channel lengths.

FIG. 21 is a graph of output resistance in MΩ-μm against channel length in μm in a logarithmic plot for the two oxide thicknesses (i.e., 12.5 nm and 50 nm).

FIG. 22 is a graph of saturation current in mA/μm at V_{DS}=650 V for various channel lengths in μm.

FIG. 23 is a graph of saturation current in mA/μm at V_{DS}=650 V vs. oxide thickness in nm for one instance of channel length of 0.3 μm.

FIG. 24 is a graph of output resistance in Ω-μm vs. oxide thickness in nm for one instance of channel length of 0.3 μm.

FIG. 25 is a schematic of an electronic switching system.

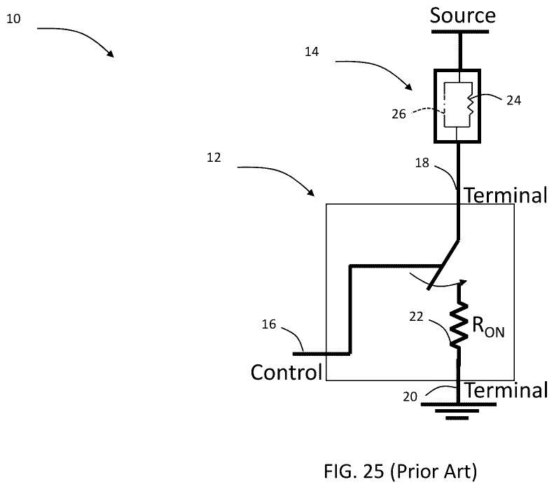

### DETAILED DESCRIPTION

For the purposes of promoting an understanding of the principles of the present disclosure, reference will now be made to the embodiments illustrated in the drawings, and specific language will be used to describe the same. It will nevertheless be understood that no limitation of the scope of this disclosure is thereby intended.

In the present disclosure, the term “about” can allow for a degree of variability in a value or range, for example, within 15%, within 10%, within 5%, or within 1% of a stated value or of a stated limit of a range.

In the present disclosure, the term “substantially” can allow for a degree of variability in a value or range, for example, within 85%, within 90%, within 95%, or within 99% of a stated value or of a stated limit of a range.

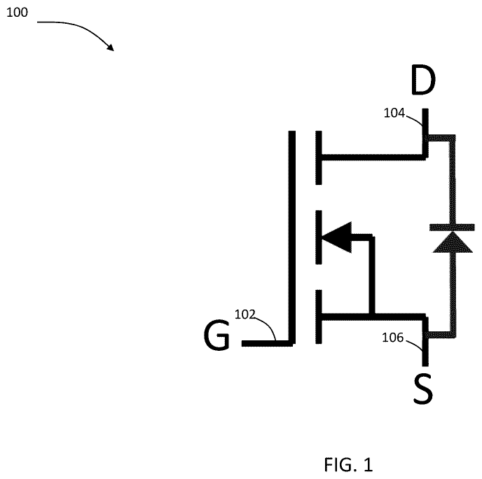

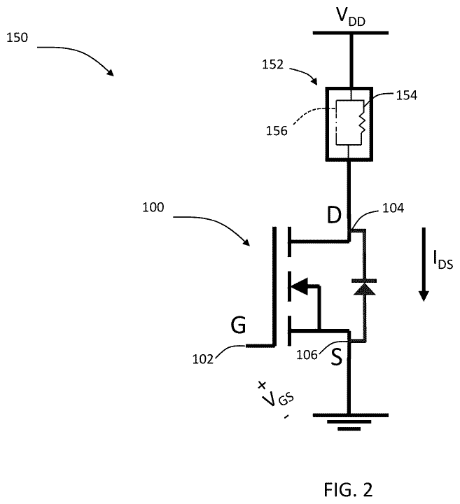

Referring to FIG. 1, a power device 100, e.g., a power metal oxide semiconductor field effect transistor (MOSFET) is shown, as known to a person having ordinary skill in the art, including three terminals gate 102, drain 104, and source 106. In the off-state, the power device 100 blocks current passing between the drain 104 and source 106 up to its maximum rated voltage while allowing only a negligible leakage current to flow. In the normal on-state, the power device 100 permits a high current to flow between the drain 104 and source 106, limited by the load resistance (see FIG. 2) of the circuit to which it is connected and the on-resistance of the power device 100, further described below. In either case the resulting power dissipation in the device remains low enough to prevent thermal damage to the device. In the power device 100 and many other power semiconductor devices, the on-state current is controlled by a metal-oxide-semiconductor (MOS) structure. This structure provides a high input impedance at the gate 102 that is desirable for circuit design considerations (i.e., improvement over bipolar devices requiring continuous electrical current to activate the device, i.e., to turn it on). Examples of MOS-controlled devices include the power MOS field effect transistors (MOSFETs, e.g., silicon carbide MOSFET (SiC MOSFET)), and MOS-controlled thyristors.

Referring to FIG. 2, an electronic switching system 150 is shown with the power device 100 of FIG. 1 shown as being coupled to a load 152. The load 152 includes a load resistor 154, which as discussed above limits the current passing through the power device 100 (shown as I_{DS}) when in the on state. When the power device 100 is in the on state, a channel is created (described below), allowing current to pass from the drain 104 to the source 106. The power device 100 is fully on when sufficient voltage is applied to the gate such that
V_{GS}>V_{T}, where
V_{GS} is the voltage between the gate 102 and the source 106 terminals, and
V_{T} is a threshold voltage which depends on the power device 100 and is the threshold value of
V_{GS} above which the power device 100 begins to conduct load current when the drain-to-source voltage Vds>0.

However, if the load resistance suddenly drops (as shown in the dashed line in FIG. 2, going from the load resistor 154 to the shorted state 156), for instance due to a short in the winding of a motor coil, the power device 100 would be suddenly subjected to both high voltage of the supply (V_{DD}) and high current, producing an unsustainably high internal power dissipation. Under these conditions, the current passing between drain and source is considered to be at saturation. The limiting current density when the power device 100 is in saturation can be written as:

J_{load,sat}=I_{DSAT}/A=(V_{GS}−V_{T})/2R_{ch,sp}, (1)
where V_{GS} is the gate-to-source voltage,
J_{DSAT} I_{DSAT}/A is the saturated drain current density, and
R_{ch,sp} is product of channel resistance R_{c}h and the unit cell area of the power device structure. Since the power that the device dissipates internally in the on-state is proportional to R_{ch,sp}, it is a goal of the power device designers to reduce R_{ch,sp}, which increases the saturation load current J_{load,sat}. This condition will ultimately lead to the thermal destruction of the power device 100 if the condition is not interrupted quickly. Power electronic circuits generally include a short-circuit protection scheme to mitigate this condition, in which the gate driver turns the power transistor off when a short circuit condition is detected. However, this process takes a finite amount of time, typically on the order of 1-10 μs. A robust power transistor must be able to absorb the energy of this event without failure. The ability of a transistor to survive these events is characterized by the short-circuit withstand time, which is defined as the maximum time that the device can be subjected to the short-circuit condition before failure occurs. While the criteria for “failure” has not been well defined in the prior art, failure according to the present disclosure includes failure due to unacceptable changes in device parameters such that the device no longer meets its specifications, or the introduction of latent damage that reduces the long-term/lifetime reliability of the device, while difficult to detect in practice.

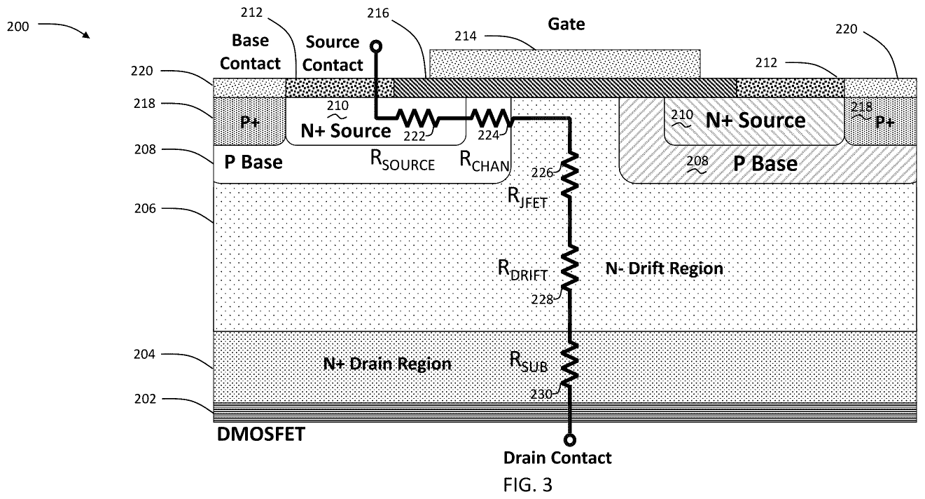

Therefore, from one perspective, two important parameters of a power semiconductor device of interest in studying robustness of the device are the specific on-resistance R_{ch,sp} and the short-circuit withstand time (SCWT). The specific on-resistance includes several internal resistances (see FIG. 3, where an exemplary schematic is shown of power device, e.g., a MOSFET) that are additive, and one of these is the channel specific resistance R_{ch,sp} (shown in FIG. 3 as R_{CHAN}). In SiC, due to the low mobility of electrons in the MOS channel, the channel resistance can be the dominant term. As discussed above, the SCWT is the length of time the device can survive in the on-state if the load is suddenly shorted (see FIG. 2, going from the load resistor 154 to the shorted state 156). If this happens, the terminal voltage across the device (i.e., V_{DS}, voltage across terminals 104 and 106) rises to the supply voltage, V_{DD} (e.g., above 10 kV, depending on the application), and the load terminal current (i.e., the current entering the terminal 104) rises to the saturation current J_{load,sat}. The power dissipated in the semiconductor is the product of the terminal current and terminal voltage, and in some cases can be in the hundreds of kW. This sudden increase in current through the power device 100 and voltage across it, causes rapid internal heating, leading to failure of the power device 100. Thus, the SCWT is the length of time the device can survive before failure. As a result, it is the goal of the designer to minimize R_{on,sp} and maximize the SCWT, but as provided herein, these are conflicting goals, since reducing R_{ch,sp} increases J_{load,sat} which reduces SCWT.

The designer cannot sacrifice on-state performance of the device by increasing R_{on,sp} in order to reduce SCWT, since increasing R_{on,sp} has deleterious effects for normal operations of the power device 100 (i.e., under normal working conditions and not short-circuit conditions). The present disclosure breaks the relationship between R_{ch,sp} and J_{load,sat}, allowing the designer to reduce J_{load,sat} without increasing R_{on,sp}.

A metal-oxide semiconductor (MOS) power device's input structure includes a gate insulator between a controlling electrode, i.e., the gate, and the surface of the semiconductor, i.e., a source region, base region, or drift region shown in FIG. 3. Referring To FIG. 3, a cross sectional view of a metal-oxide-semiconductor (MOS) power device 200, and in particular a double-diffused MOS field effect transistor (DMOSFET), is shown. It should be appreciated that the term DMOSFET originated with double-diffused silicon. While diffusion is impractical in SiC and the above-referenced SiC power device of the present disclosure are formed by double implantation, the same acronym as the silicon device is used for SiC. The MOS power device 200 includes a drain electrode 202 (identified as “Drain Contact”) in electrical contact with a drain semiconductor region 204 (shown as “N+Drain Region”) of a first conductivity type (N type shown, however as explained below the first conductivity type can be P type while a second conductivity type be N type). The material of the drain semiconductor region 204 can be doped silicon, doped silicon carbide, or other suitable semiconductor material (e.g., gallium arsenide (GaAs) or gallium nitride (GaN)). More is discussed below regarding the doping level. The MOS Power device 200 also includes a drift semiconductor region 206 of the first conductivity type (shown as “N-Drift Region”, however as explained below the first conductivity type can be P type while the second conductivity type can be N type). The drift semiconductor region 206 is coupled to the drain semiconductor region 204. The material of the drift semiconductor region 206 can be doped silicon, doped silicon carbide, or other suitable semiconductor material (e.g., gallium arsenide (GaAs) or gallium nitride (GaN)). The MOS power device 200 further includes a base semiconductor region 208 of the second conductivity type (shown as “P Base”, however as explained below the second conductivity type can be N type while the first conductivity type can be P type). The base semiconductor region 208 is coupled to the drift semiconductor region 206 through the pn junction at the interface between these two regions. The material of the base semiconductor region 208 can be doped silicon, doped silicon carbide, or other suitable semiconductor material. The MOS power device 200 further includes a source semiconductor region 210 of the first conductivity type (shown as “N+Source”, however as explained below the first conductivity type can be P type while the second conductivity type can be N type). The source semiconductor region 210 is coupled to the base semiconductor region 208 and isolated by the base semiconductor region 208 from the drift semiconductor region 206. The material of the source semiconductor region 210 can be doped silicon, doped silicon carbide, or other suitable semiconductor material. The MOS power device 200 further includes a source electrode 212 (shown as “Source Contact”) that is coupled to the source semiconductor region 210, making electrical contact therewith. The MOS power device 200 further includes a gate electrode 214 (shown simply as “Gate”) that is provided adjacent at least a portion of but isolated from i) the base semiconductor region 208, ii) the source semiconductor region 210, and iii) the drift semiconductor region 206 by a dielectric material 216. The dielectric material 216 has a thickness between 1 nm and 30 nm (or between 1 nm and 25 nm, or between 1 nm and 20 nm, or between 1 nm and 15 nm, or between 1 nm and 10 nm, or between 1 and 5 nm) multiplied by a correction factor defined as a ratio of dielectric permittivity of the dielectric material and the permittivity of silicon dioxide. The drift semiconductor region 206 has a sufficient thickness and doping to withstand greater than e.g., 100 V (this value depends on the semiconductor material—in silicon the drift region may only be designed to withstand greater than 20-30 V; in SiC, the drift region typically withstands more than 400-500 V; and GaN is above 50-100 V) between the drain electrode 202 and the source electrode 212 when substantially no current is flowing through the drain electrode 202. The MOS power device 200 further includes a semiconductor region 218 of the second conductivity type (shown as “P+”, however as explained below the second conductivity type can be N type while the first conductivity type be P type). The semiconductor region 218 is coupled to the base semiconductor region 208 and isolated by the base semiconductor region 208 from the drift semiconductor region 206. The material of the semiconductor region 218 can be doped silicon, doped silicon carbide, or other suitable semiconductor material. The MOS power device 200 further includes a base contact 220 (shown as “Base Contact”) that is coupled to the semiconductor region 218, making electrical contact therewith.

If the gate-to-source voltage (V_{GS}) is above the threshold voltage V_{T}, a conducting channel (not shown, but known to a person having ordinary skill in the art) is induced along the surface of the semiconductor under the gate and the power device turns on. The gate insulator (i.e., the dielectric material 216) is a dielectric, and the most common dielectric is SiO₂. Other dielectric materials could also be used, for example Al₂O₃, Si₃N₄, HfO₂, ZrO₂, or layered combinations thereof.

Each dielectric material can be characterized in terms of two electric fields, the breakdown field (i.e., critical field) E_{CR} where the dielectric fails and no longer acts as an insulator, and the maximum reliable field E_{REL} beyond which the dielectric does not satisfy long-term reliability requirements. For SiO₂, E_{CR} is about 10 MV/cm and E_{REL} is about 4 MV/cm. Other dielectrics can each be characterized with particular values for E_{CR} and E_{REL}. The electric field in the dielectric material is given by:

Eᵢₙₛ=(V_{GS}−φ_{GS}−2ψ_{F})/tᵢₙₛ (2)
where V_{GS} is the applied voltage between the gate and the source in volts,
φ_{GS} is the work function difference between the gate material and the semiconductor in the channel region in volts,
ψ_{F} is the bulk Fermi potential of the semiconductor material in the channel region (determined by its doping) in volts, and
tᵢₙₛ is the thickness of the dielectric material between the gate and the semiconductor in centimeters.

In the event of a short circuit, shown as a dashed line in FIG. 2 in the load 152, a high internal power dissipation occurs which causes extremely rapid adiabatic heating of the power device 100 or 200. The generated heat does not have sufficient time to diffuse outward to any attached cooling apparatus (e.g. a heat sink) via normal thermal conduction before the device fails. The temperature rise ΔT that occurs inside the device during a short-circuit event of duration t_{sc} seconds can therefore be estimated as:

$$Δ T = \frac{P}{ρ {C}_{p} V} {t}_{sc} \qquad ( 3 )$$

where P is the power dissipated during the short circuit event in watts,
ρ is the density of the semiconductor material in g/cm³,
t_{sc} is the short circuit withstand time,
Cₚ is the specific heat capacity in J/g/° C. of the semiconductor material, and
V is the heated volume of the device in cm³. The power dissipation is simply the current flowing in the device multiplied by the voltage across the drain and source terminals, i.e., P=I_{D}×V_{DS}.

In the MOS power device 200 shown in FIG. 3, the dielectric material 216 includes one or more layers of silicon dioxide, aluminum oxide, zirconium oxide, hafnium oxide, gallium oxide, lanthanum oxide, lanthanum aluminum oxide, beryllium oxide, or other suitable dielectric.

In the MOS power device shown in FIG. 3, the material of the source, drain, and gate electrodes 212, 214, and 202, respectively, includes one or more of copper, silver, gold, carbon, graphite, nickel, titanium, aluminum, polysilicon, and graphene. According to one embodiment, the ohmic metal used on N-type regions such as the source and drain is nickel. The ohmic metal used on P-type regions such as the base is aluminum or nickel. It should be appreciated that these metals are used in SiC, while other metals may be used for other MOSFETs such as silicon MOSFETs and GaN MOSFETs. These metals are annealed at a high temperature, e.g., about 1000° C. —however, lower temperatures may be acceptable for various other semiconductor material, e.g., GaN—to form ohmic contacts, then they are covered with a thick (4-5 μm) conductive metal such as aluminum. A thin layer of titanium is typically used for adhesion, covered with a thicker layer of aluminum containing about 0.5% copper.

In the MOS power device 200 shown in FIG. 3, the drift semiconductor region 206 is in contact with the drain semiconductor region 204.

In the MOS power device 200 shown in FIG. 3, the base semiconductor region 208 is in contact with the drift semiconductor region 206.

In the MOS power device 200 shown in FIG. 3, the source semiconductor region 210 is in contact with the base semiconductor region 208.

In the MOS power device 200 shown in FIG. 3, the first conductivity type is N-type and the second conductivity type is P-type.

In the MOS power device 200 shown in FIG. 3, the first conductivity type is P-type and the second conductivity type is N-type.

In the MOS power device 200 shown in FIG. 3, the drain semiconductor region 204 has a dopant level higher than a dopant level of the drift semiconductor region 206.

In the MOS power device 200 shown in FIG. 3, the source semiconductor region 210 has a dopant level higher than a dopant level of the drift semiconductor region 206.

Referring to FIG. 3, the resistance of the MOS power device 200 in the on state is represented by five units. These are: R_{SOURCE} 222, R_{CHAN} 224, R_{JFET} 226, R_{DRIFT} 228, and R_{SUB} 230, representing the source portion, the channel portion, the JFET region defined as the portion of the drift region between two adjacent base regions, the drift region portion, and the substrate portion of the MOS power device 200, respectively.

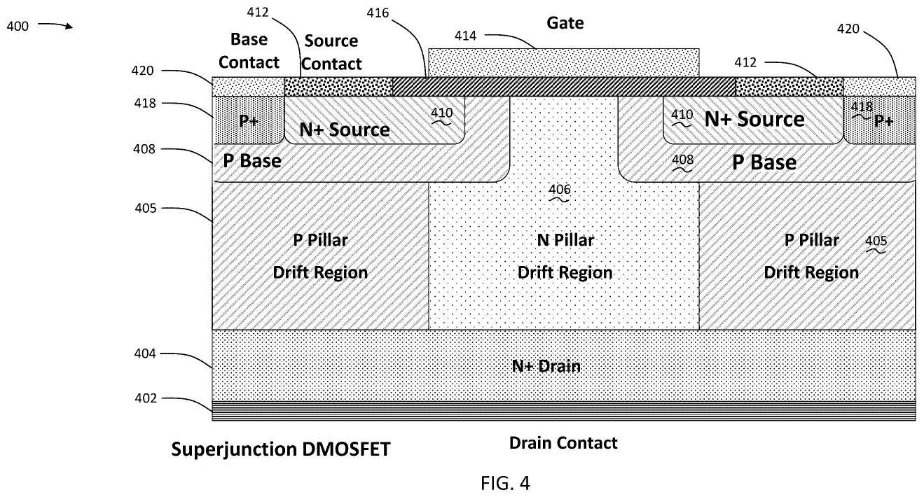

Referring to FIG. 4, a cross sectional view of a superjunction DMOSFET is shown. The description provided above for the DMOSFET in relationship with FIG. 3 applies to the superjunction DMOSFET device of FIG. 4 with the apparent differences (e.g., the drift region is comprised of alternating stacks, shown as “P Pillar”, “N Pillar”, and “P Pillar” of alternating polarities).

The MOS power device 400 includes a drain electrode 402 (identified as “Drain Contact”) in electrical contact with a drain semiconductor region 404 (shown as “N+ Drain”) of a first conductivity type (N type shown, however as explained below the first conductivity type can be P type while a second conductivity type can be N type). The material of the drain semiconductor region 404 can be doped silicon, doped silicon carbide, or other suitable semiconductor material. More is discussed below regarding the doping level. The MOS Power device 400 also includes alternating stacks, shown as “P Pillar”, “N Pillar”, and “P Pillar” of alternating conductivity types 405 and 406 of the second conductivity type and the first conductivity type (shown as “P Pillar Drift Region” and “N Pillar Drift Region”, however, as explained below the first conductivity type can be P type while a second conductivity type can be N type). The drift semiconductor regions 405 and 406 are coupled to the drain semiconductor region 404. The material of the drift semiconductor regions 405 and 406 can be doped silicon, doped silicon carbide, or other suitable semiconductor material. The MOS power device 400 further includes a base semiconductor region 408 of the second conductivity type (shown as “P Base”, however as explained below the second conductivity type can be N type while the first conductivity type can be P type). The base semiconductor region 408 is coupled to the drift semiconductor region 405 and isolated from the drain semiconductor region 404 by the pn junction at the interface between base region 408 and drift region 406. The material of the base semiconductor region 408 can be doped silicon, doped silicon carbide, or other suitable semiconductor material. The MOS power device 400 further includes a source semiconductor region 410 of the first conductivity type (shown as “N+ Source”, however as explained below the first conductivity type can be P type while the second conductivity type can be N type). The source semiconductor region 410 is coupled to the base semiconductor region 408 and isolated by the base semiconductor region 408 from the drift semiconductor regions 405 and 406. The material of the source semiconductor region 410 can be doped silicon, doped silicon carbide, or other suitable semiconductor material. The MOS power device 400 further includes a source electrode 412 (shown as “Source Contact”) that is coupled to the source semiconductor region 410, making electrical contact therewith. The MOS power device 400 further includes a gate electrode 414 (shown simply as “Gate”) that is provided adjacent at least a portion of but isolated from i) the base semiconductor region 408, ii) the source semiconductor region 410, and iii) the drift semiconductor region 406 by a dielectric material 416. The dielectric material 416 has a thickness between 1 nm and 30 nm (or between 1 nm and 25 nm, or between 1 nm and 20 nm, or between 1 nm and 15 nm, or between 1 nm and 10 nm, or between 1 and 5 nm) multiplied by a correction factor defined as a ratio of dielectric permittivity of the dielectric material and the permittivity of silicon dioxide. The drift semiconductor regions 405 and 406 have a sufficient thickness and doping to withstand greater than e.g., 100 V (this value depends on the semiconductor material—in silicon the drift region may only be designed to withstand greater than 20-30 V; in SiC, the drift region typically withstands more than 400-500 V; and GaN is above 50-100 V) between the drain electrode 402 and the source electrode 412 when substantially no current is flowing through the drain electrode 402. The MOS power device 400 further includes a semiconductor region 418 of the second conductivity type (shown as “P+ Source”, however as explained below the second conductivity type can be N type while the first conductivity type can be P type). The semiconductor region 418 is coupled to the base semiconductor region 408 and isolated by the base semiconductor region 408 from the drift semiconductor regions 405 and 406. The material of the semiconductor region 418 can be doped silicon, doped silicon carbide, or other suitable semiconductor material. The MOS power device 400 further includes a base contact 420 (shown as “Base Contact”) that is coupled to the semiconductor region 418, making electrical contact therewith.

If the gate-to-source voltage (V_{GS}) is above the threshold voltage V_{T}, a conducting channel (not shown, but known to a person having ordinary skill in the art) is induced along the surface of the semiconductor under the gate and the power device turns on. The gate insulator (i.e., the material 416) is a dielectric, and the most common dielectric is SiO₂. Other dielectric materials could also be used, for example Al₂O₃, Si₃N₄, HfO₂, ZrO₂, or layered combinations thereof.

Each dielectric material can be characterized in terms of two electric fields, the breakdown field (i.e., critical field) E_{BR} where the dielectric fails and no longer acts as an insulator, and the maximum reliable field E_{REL} beyond which the dielectric does not satisfy long-term reliability requirements. For SiO₂, E_{BR} is about 10 MV/cm and E_{REL} is about 4 MV/cm. The particular value of E_{REL} depends on the intended application, and E_{REL} may range from below 1 MeV/cm to just below E_{BR}. Other dielectrics can each be characterized with particular values for E_{BR} and E_{REL}.

In the event of a short circuit, shown as a dashed line in FIG. 2 in the load 152, a high internal power dissipation occurs which causes extremely rapid adiabatic heating of the power device 100 or 400. The generated heat does not have sufficient time to diffuse outward to any attached cooling apparatus (e.g. a heat sink) via normal thermal conduction before the device fails. The temperature rise ΔT that occurs inside the device during a short-circuit event of duration t_{sc} seconds can therefore be estimated using equation (3) provided above.

In the MOS power device 400 shown in FIG. 4, the dielectric material 416 includes one or more layers of silicon dioxide, aluminum oxide, zirconium oxide, hafnium oxide, gallium oxide, lanthanum oxide, lanthanum aluminum oxide, and beryllium oxide.

In the MOS power device shown in FIG. 4, the material of the source, drain, and gate electrodes 412, 414, and 402, respectively, includes one or more of copper, silver, gold, carbon, graphite, nickel, titanium, aluminum, polysilicon, and graphene. According to one embodiment, the ohmic metal used on N-type regions such as the source and drain is nickel. The ohmic metal used on P-type regions such as the base is aluminum or nickel. It should be appreciated that these metals are used in SiC, while other metals may be used for other MOSFETs such as silicon MOSFETs and GaN MOSFETs. These metals are annealed at a high temperature, e.g., about 1000° C.—however, lower temperatures may be acceptable for various other semiconductor material, e.g., GaN—to form ohmic contacts, then they are covered with a thick (4-5 μm) conductive metal such as aluminum. A thin layer of titanium is typically used for adhesion, covered with a thicker layer of aluminum containing about 0.5% copper.

In the MOS power device 400 shown in FIG. 4, the drift semiconductor regions 405 and 406 are in contact with the drain semiconductor region 404.

In the MOS power device 400 shown in FIG. 4, the base semiconductor region 408 is in contact with the drift semiconductor regions 405 and 406.

In the MOS power device 400 shown in FIG. 4, the source semiconductor region 410 is in contact with the base semiconductor region 408.

In the MOS power device 400 shown in FIG. 4, the first conductivity type is N-type and the second conductivity type is P-type.

In the MOS power device 400 shown in FIG. 4, the first conductivity type is P-type and the second conductivity type is N-type.

In the MOS power device 400 shown in FIG. 4, the drain semiconductor region 404 has a dopant level higher than a dopant level of the drift semiconductor regions 405 or 406.

In the MOS power device 400 shown in FIG. 4, the source semiconductor region 410 has a dopant level higher than a dopant level of the drift semiconductor regions 405 or 406.

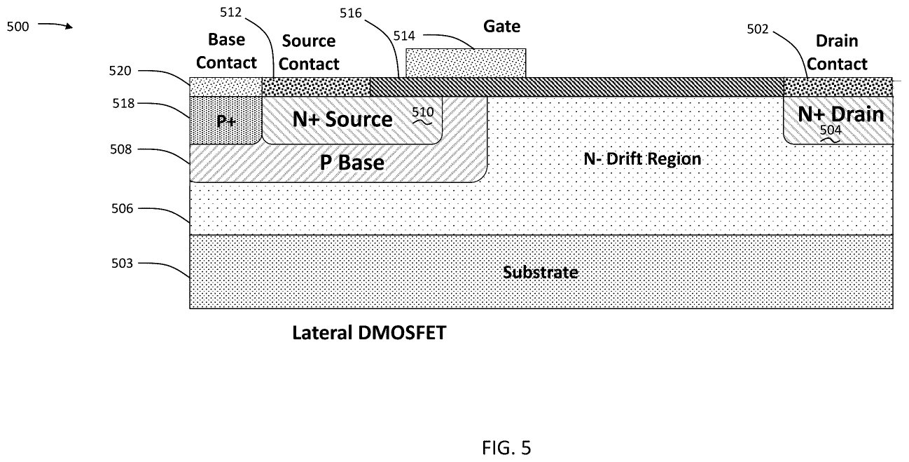

Referring to FIG. 5, a cross sectional view of a lateral DMOSFET is shown. The description provided above for the DMOSFET in relationship with FIG. 3 applies to the lateral DMOSFET device of FIG. 5 with the apparent differences (e.g., drain and source semiconductor regions are laterally juxtaposed as well as the associated source and drain electrodes, shown in FIG. 5 as “Contacts”).

The MOS lateral power device 500 includes a drain electrode 502 (identified as “Drain Contact”) in electrical contact with a drain semiconductor region 504 (shown as “N+ Drain Region”) of a first conductivity type (N type shown, however as explained below the first conductivity type can be P type while a second conductivity type can be N type). The material of the drain semiconductor region 504 can be doped silicon, doped silicon carbide, or other suitable semiconductor material. More is discussed below regarding the doping level. The MOS lateral power device 500 includes a substrate 503 (identified as “Substrate”). The MOS Power device 500 also includes a drift semiconductor region 506 of a first conductivity type (shown as “N-Drift Region”, however as explained below the first conductivity type can be P type while a second conductivity type can be N type). The drift semiconductor region 506 is coupled to the substrate 503. The material of the drift semiconductor region 506 can be doped silicon, doped silicon carbide, or other suitable semiconductor material. The MOS lateral power device 500 further includes a base semiconductor region 508 of the second conductivity type (shown as “P Base”, however as explained below the second conductivity type can be N type while the first conductivity type can be P type). The base semiconductor region 508 is coupled to the drift semiconductor region 506 and isolated from the drift semiconductor region 506 by the pn junction at the interface between these two regions. The material of the base semiconductor region 508 can be doped silicon, silicon carbide, or other suitable semiconductor material. The MOS lateral power device 500 further includes a source semiconductor region 510 of the first conductivity type (shown as “N+ Source”, however as explained below the first conductivity type can be P type while the second conductivity type can be N type). The source semiconductor region 510 is coupled to the base semiconductor region 508 and isolated by the base semiconductor region 508 from the drift semiconductor region 506. The material of the source semiconductor region 510 can be doped silicon, doped silicon carbide, or other suitable semiconductor material. The MOS lateral power device 500 further includes a source electrode 512 (shown as “Source Contact”) that is coupled to the source semiconductor region 510, making electrical contact therewith. The MOS lateral power device 500 further includes a gate electrode 514 (shown simply as “Gate”) that is provided adjacent at least a portion of but isolated from i) the base semiconductor region 508, ii) the source semiconductor region 510, and iii) the drift semiconductor region 506 by a dielectric material 516. The dielectric material 516 has a thickness between 1 nm and 30 nm (or between 1 nm and 25 nm, or between 1 nm and 20 nm, or between 1 nm and 15 nm, or between 1 nm and 10 nm, or between 1 and 5 nm) multiplied by a correction factor defined as a ratio of dielectric permittivity of the dielectric material and the permittivity of silicon dioxide. The drift semiconductor region 506 has a sufficient lateral dimension and doping to withstand greater than e.g., 100 V (this value depends on the semiconductor material—in silicon the drift region may only be designed to withstand greater than 20-30 V; in SiC, the drift region typically withstands more than 400-500 V; and GaN is above 50-100 V) between the drain electrode 502 and the source electrode 512 when substantially no current is flowing through the drain electrode 502. The MOS lateral power device 500 further includes a semiconductor region 518 of the second conductivity type (shown as “P+”, however as explained below the second conductivity type can be N type while the first conductivity type can be P type). The semiconductor region 518 is coupled to the base semiconductor region 508 and isolated by the base semiconductor region 508 from the drift semiconductor region 506. The material of the semiconductor region 518 can be doped silicon, doped silicon carbide, or other suitable semiconductor material. The MOS lateral power device 500 further includes a base contact 520 (shown as “Base Contact”) that is coupled to the semiconductor region 518, making electrical contact therewith.

If the gate-to-source voltage (V_{GS}) is above the threshold voltage V_{T}, a conducting channel (not shown, but known to a person having ordinary skill in the art) is induced along the surface of the semiconductor under the gate and the power device turns on. The gate insulator (i.e., the material 516) is a dielectric, and the most common dielectric is SiO₂. Other dielectric materials could also be used, for example Al₂O₃, Si₃N₄, HfO₂, ZrO₂, or layered combinations thereof.

Each dielectric material can be characterized in terms of two electric fields, the breakdown field (i.e., critical field) E_{CR} where the dielectric fails and no longer acts as an insulator, and the maximum reliable field E_{REL} beyond which the dielectric does not satisfy long-term reliability requirements. For SiO₂, E_{CR} is about 10 MV/cm and E_{REL} is about 4 MV/cm. Other dielectrics can each be characterized with particular values for E_{CR} and E_{REL}.

In the event of a short circuit, shown as a dashed line in FIG. 2 in the load 152, a high internal power dissipation occurs which causes extremely rapid adiabatic heating of the power device 100 or 500. The generated heat does not have sufficient time to diffuse outward to any attached cooling apparatus (e.g. a heat sink) via normal thermal conduction before the device fails. The temperature rise ΔT that occurs inside the device during a short-circuit event of duration t_{sc} seconds can therefore be estimated as provided be equation (3) provided above.

In the MOS lateral power device 500 shown in FIG. 5, the dielectric material 516 includes one or more layers of silicon dioxide, aluminum oxide, zirconium oxide, hafnium oxide, gallium oxide, lanthanum oxide, lanthanum aluminum oxide, and beryllium oxide.

In the MOS lateral power device shown in FIG. 5, the material of the source, drain, and gate electrodes 512, 514, and 502, respectively, includes one or more of copper, silver, gold, carbon, graphite, nickel, titanium, aluminum, polysilicon, and graphene. According to one embodiment, the ohmic metal used on N-type regions such as the source and drain is nickel. The ohmic metal used on P-type regions such as the base is aluminum or nickel. It should be appreciated that these metals are used in SiC, while other metals may be used for other MOSFETs such as silicon MOSFETs and GaN MOSFETs. These metals are annealed at a high temperature, e.g., about 1000° C. —however, lower temperatures may be acceptable for various other semiconductor material, e.g., GaN—to form ohmic contacts, then they are covered with a thick (4-5 μm) conductive metal such as aluminum. A thin layer of titanium is typically used for adhesion, covered with a thicker layer of aluminum containing about 0.5% copper.

The material for the substrate 503 can be any one of Si, SiC, graphene, glass, sapphire, ceramic, or other suitable substrates known to a person having ordinary skill in the art.

In the MOS lateral power device 500 shown in FIG. 5, the drift semiconductor region 506 is in contact with the substrate 503.

In the MOS lateral power device 500 shown in FIG. 5, the base semiconductor region 508 is in contact with the drift semiconductor region 506.

In the MOS lateral power device 500 shown in FIG. 5, the source semiconductor region 510 is in contact with the base semiconductor region 508.

In the MOS lateral power device 500 shown in FIG. 5, the first conductivity type is N-type and the second conductivity type is P-type.

In the MOS lateral power device 500 shown in FIG. 5, the first conductivity type is P-type and the second conductivity type is N-type.

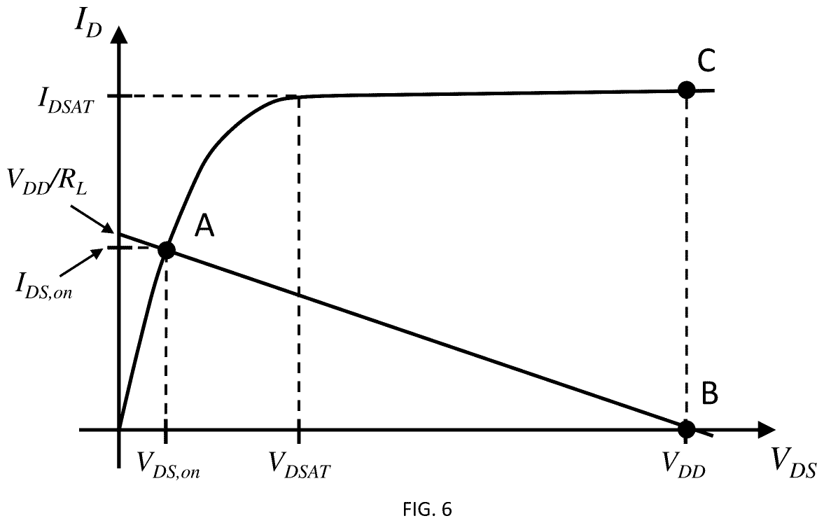

Referring to FIG. 6, a graph of drain current I_{D} of a MOSFET as a function of V_{DS} for a gate voltage greater than the threshold voltage V_{T} is illustrated. There are two distinct regions of operation, the linear region, also called the ohmic region where the I_{DS} (shown as I_{D}) current is linearly related to the V_{DS} where V_{DS}<V_{DSAT}; and the saturation region (V_{DS}>V_{DSAT}) where the current becomes roughly constant regardless of the V_{DS}. The normal on-state, point A, occurs in the linear region while the normal off state occurs at point B with V_{GS}<V_{T}. The short-circuit condition occurs at point C, with the drain current equal to the saturation current I_{DSAT}, and the drain voltage substantially equal to the supply voltage (V_{DD}, see FIG. 2), which could be as high as the maximum rated drain voltage of the power device.

In one exemplary situation where the supply voltage is half the maximum rated drain voltage, equation (3) can be rewritten as:

$$Δ T = \frac{{I}_{DSAT} {V}_{BR}}{2 ρ {C}_{p} V} {t}_{sc} \qquad ( 4 )$$

where V_{BR} is the blocking voltage of the device. The heated volume of a power device is approximately equal to the product of the active area and the thickness of the voltage blocking layer (V=A×d). The thickness in a typical power MOSFET is proportional to the required blocking voltage V_{BR}, and inversely proportional to the critical electric field of the semiconductor material: d=2 V_{BR}/E_{CR}. Rewriting current density as a function of I_{DSAT}, J_{DSAT} I_{DSAT}/A, equation (4) can be rewritten as:

$$Δ T = \frac{{E}_{CR} {J}_{DSAT}}{4 ρ {C}_{p}} {t}_{sc} . \qquad ( 5 )$$

Solving equation (5) for the short-circuit withstand time t_{sc}:

$${t}_{sc} = \frac{4 ρ {C}_{p} Δ T}{{E}_{CR} {J}_{DSAT}} . \qquad ( 6 )$$

From equation (6), it can be observed that the short-circuit withstand time of a power MOSFET is inversely proportional to the saturation current density. Minimizing this parameter will therefore improve robustness to short circuit events.

Devices are typically rated by their on-resistance, which is the reciprocal of the slope of the nearly linear region of the I_{D}−V_{DS} plot shown in FIG. 6, from the origin to the operating point A. As discussed above and shown in FIG. 3, the on-resistance of a power device is the sum of several components, including the channel resistance R_{ch} 224, drift or blocking layer resistance 228, substrate resistance 230, etc. Of these, for SiC power MOSFETs with blocking voltages less than about 1 kV, the channel resistance becomes dominant, and is given by the following equation (7), when normalized to total device area:

$${R}_{ch , sp} = {R}_{ch} A = \frac{{L}_{ch} A}{{μ}_{n} {W}_{ch} {C}_{ox} ( {V}_{GS} - {V}_{T} )} , \qquad ( 7 )$$

where L_{ch} and W_{ch} are the length and width of the MOSFET channel,
A is the device area,
μₙ is the mobility of electrons in the channel,
Cₒₓ is the capacitance of the gate insulator per unit area,
V_{GS} is the gate-to-source voltage, and
V_{T} is the threshold voltage. The saturation current density, in the simplest form, is given by:

$${J}_{DSAT} = \frac{{μ}_{n} {W}_{ch} {C}_{ox} {( {V}_{GS} - {V}_{T} )}^{2}}{2 {L}_{ch} A} = \frac{{V}_{GS} - {V}_{T}}{2 {R}_{ch , sp}} \qquad ( 8 )$$

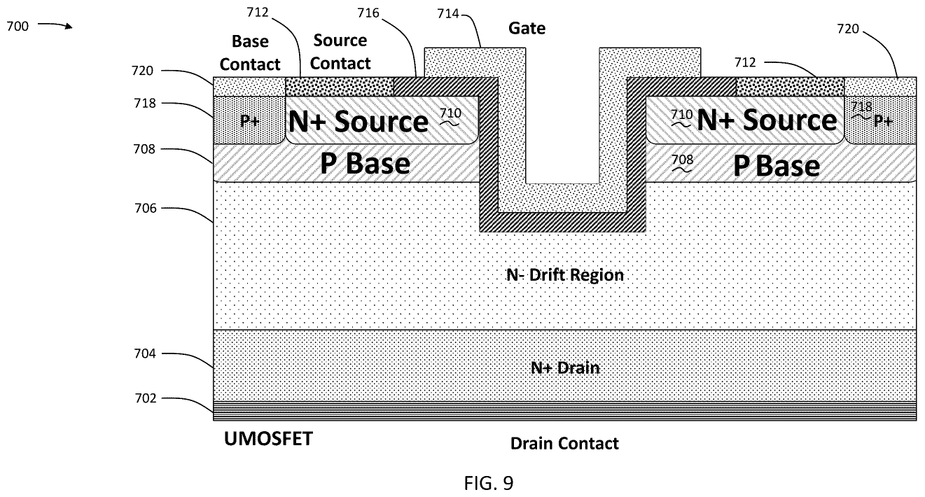

To reduce the active area, and thus the cost, of a power MOSFET, device engineers can reduce R_{ch,sp} in a number of ways, for example by scaling the unit cell area of the device through sub-micron photolithography, or by adopting a more compact cell design such as the UMOSFET (example of which is shown in FIG. 9). However, anything that is done to reduce R_{ch,sp} also increases J_{DSAT}, and given the inverse proportionality thus reduces the short-circuit withstand time.

The saturation current density can be reduced by simply lowering the gate overdrive voltage V_{GS}−V_{T}, but this would normally increase the specific on-resistance by reducing the electron density in the channel, as shown by equation (7). However, simultaneously increasing Cₒₓ by the same factor, keeping the term Cₒₓ(V_{GS}−V_{T}) substantially constant, maintains the same R_{ch,sp}, but decreases J_{DSAT}, since J_{DSAT} depends on the square of the overdrive voltage. The gate insulator capacitance is given by:

Cᵢₙₛ=∈ᵢₙₛ/tᵢₙₛ (9),
where ∈ᵢₙₛ is the dielectric constant of the insulator, and tᵢₙₛ is the thickness of the insulator. Therefore, the insulator capacitance can be increased by either replacing silicon dioxide, which has a dielectric constant of 3.9, with a high-κdielectric as has been done in high-performance Si CMOS transistors in recent years, or by simply reducing the thickness of the gate insulator. The typical gate oxide thickness in current SiC MOSFETs is 40-50 nm, leaving significant room for reduction before problems such as gate leakage become significant.

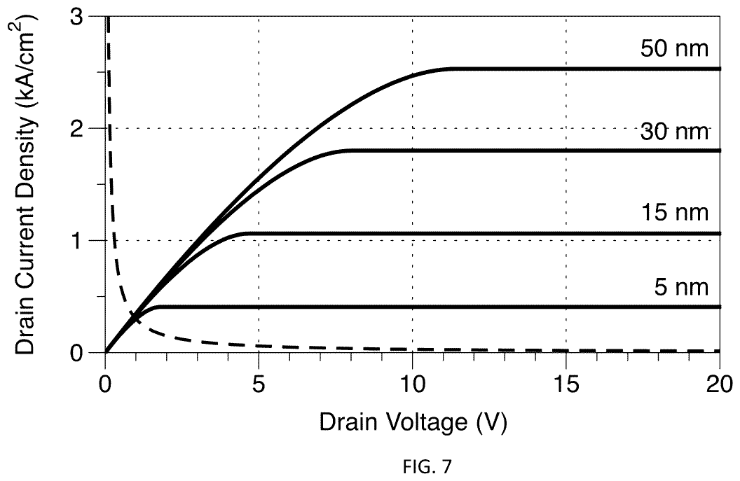

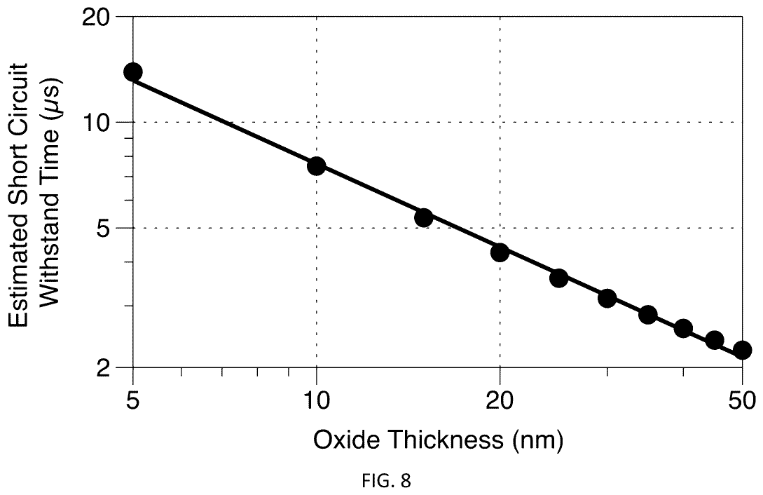

To illustrate the potential of this method of producing a more robust SiC power MOSFET, reference is made to FIG. 7 which shows calculated current density vs. drain voltage curves for a 900 V SiC DMOSFET with gate oxide thicknesses varying from 5-50 nm. With a reduction in oxide thickness, the gate voltage is lowered to maintain a constant oxide electric field, thus maintaining oxide reliability. As is clearly illustrated, reducing the oxide thickness from 50 nm to 5 nm would result in a factor of 6 reduction in J_{DSAT} (i.e., from about 3 to about 0.5 kA/cm² on the y-axis). It should be noted that the slope of the J-V curves near the origin, i.e. the specific on-resistance, does not change. Also plotted in FIG. 7 is a continuous power dissipation limit of 300 W/cm² (in dashed lines). The normal on-state operating point would be at the intersection of this power limit and the I-V curves. Note that the operating point does not change appreciatively as the oxide thickness is reduced. The only significant change is that the gate voltage must be reduced from about 27 V to about 9 V. Using equation (6), FIG. 8 shows the estimated increase in short circuit withstand time with this decrease in oxide thickness. This graph shows an inverse relationship between the short circuit withstand time and the thickness of the oxide. For example for oxide thickness of 5 nm, the short circuit withstand time can be as long as 15 μs. It should be understood that the specific values of short circuit withstand time cited above depend on the assumed maximum allowable temperature of the structure ΔT, and different assumed values of ΔT result in different values of short circuit withstand from those cited above.

Thus reducing the oxide thickness at the same time as reducing the gate drive voltage (V_{GS}−V_{T}) reduces J_{DSAT}, which increases the short-circuit withstand time, substantially unaffecting the R_{ch} which can impact the on resistance.

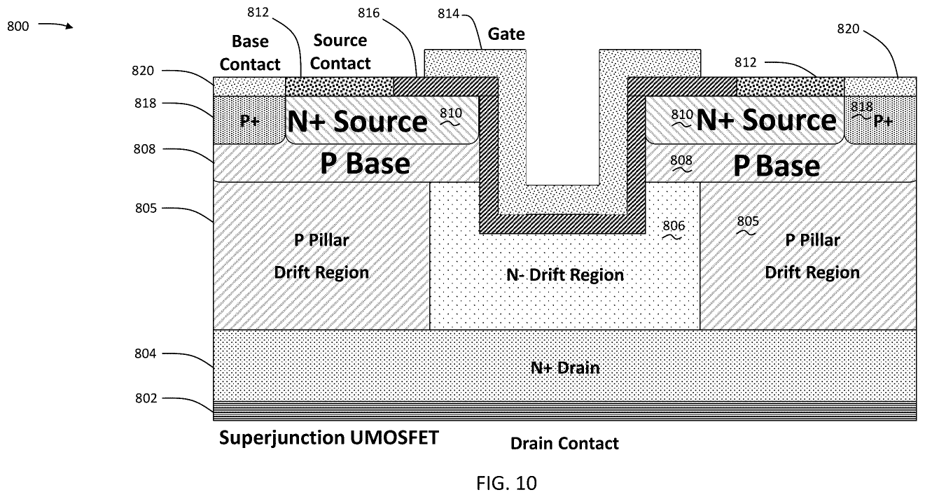

With reference to FIGS. 9 and 10 cross sectional views of a UMOSFET and a superjunction UMOSFET are shown.

Referring To FIG. 9, a cross sectional view of a MOS power device 700, and in particular a UMOSFET, is shown. The MOS power device 700 includes a drain electrode 702 (identified as “Drain Contact”) in electrical contact with a drain semiconductor region 704 (shown as “N+ Drain”) of a first conductivity type (N type shown, however as explained below the first conductivity type can be P type while a second conductivity type be N type). The material of the drain semiconductor region 704 can be doped silicon, doped silicon carbide, or other suitable semiconductor material (e.g., gallium arsenide (GaAs) or gallium nitride (GaN)). More is discussed below regarding the doping level. The MOS Power device 700 also includes a drift semiconductor region 706 of the first conductivity type (shown as “N-Drift Region”, however as explained below the first conductivity type can be P type while the second conductivity type can be N type). The drift semiconductor region 706 is coupled to the drain semiconductor region 704. The material of the drift semiconductor region 706 can be doped silicon, doped silicon carbide, or other suitable semiconductor material (e.g., gallium arsenide (GaAs) or gallium nitride (GaN)). The MOS power device 700 further includes a base semiconductor region 708 of the second conductivity type (shown as “P Base”, however as explained below the second conductivity type can be N type while the first conductivity type can be P type). The base semiconductor region 708 is coupled to the drift semiconductor region 706 through the pn junction at the interface between these two regions. The material of the base semiconductor region 708 can be doped silicon, doped silicon carbide, or other suitable semiconductor material. The MOS power device 700 further includes a source semiconductor region 710 of the first conductivity type (shown as “N+ Source”, however as explained below the first conductivity type can be P type while the second conductivity type can be N type). The source semiconductor region 710 is coupled to the base semiconductor region 708 and isolated by the base semiconductor region 708 from the drift semiconductor region 706. The material of the source semiconductor region 710 can be doped silicon, doped silicon carbide, or other suitable semiconductor material. The MOS power device 700 further includes a source electrode 712 (shown as “Source Contact”) that is coupled to the source semiconductor region 710, making electrical contact therewith. The MOS power device 700 further includes a gate electrode 714 (shown simply as “Gate”) that is provided adjacent at least a portion of but isolated from i) the base semiconductor region 708, ii) the source semiconductor region 710, and iii) the drift semiconductor region 706 by a dielectric material 716. The dielectric material 716 has a thickness between 1 nm and 30 nm (or between 1 nm and 25 nm, or between 1 nm and 20 nm, or between 1 nm and 15 nm, or between 1 nm and 10 nm, or between 1 and 5 nm) multiplied by a correction factor defined as a ratio of dielectric permittivity of the dielectric material and the permittivity of silicon dioxide. The gate electrode 714 and the dielectric material 716 both are U-shaped, to be contrasted with the gate electrode 214 and the dielectric material 216 of the DMOSFET shown in FIG. 3. The drift semiconductor region 706 has a sufficient thickness and doping to withstand greater than e.g., 100 V (this value depends on the semiconductor material—in silicon the drift region may only be designed to withstand greater than 20-30 V; in SiC, the drift region typically withstands more than 400-500 V; and GaN is above 50-100 V) between the drain electrode 702 and the source electrode 712 when substantially no current is flowing through the drain electrode 702. The MOS power device 700 further includes a semiconductor region 718 of the second conductivity type (shown as “P+”, however as explained below the second conductivity type can be N type while the first conductivity type can be P type). The semiconductor region 718 is coupled to the base semiconductor region 708 and isolated by the base semiconductor region 708 from the drift semiconductor region 706. The material of the semiconductor region 718 can be doped silicon, doped silicon carbide, or other suitable semiconductor material. The MOS power device 700 further includes a base contact 720 (shown as “Base Contact”) that is coupled to the semiconductor region 718, making electrical contact therewith.

If the gate-to-source voltage (V_{GS}) is above the threshold voltage V_{T}, a conducting channel (not shown, but known to a person having ordinary skill in the art) is induced along the surface of the semiconductor under the gate and the power device turns on. The gate insulator (i.e., the dielectric material 716) is a dielectric, and the most common dielectric is SiO₂. Other dielectric materials could also be used, for example Al₂O₃, Si₃N₄, HfO₂, ZrO₂, or layered combinations thereof.

Each dielectric material can be characterized in terms of two electric fields, the breakdown field (i.e., critical field) E_{BR} where the dielectric fails and no longer acts as an insulator, and the maximum reliable field E_{REL} beyond which the dielectric does not satisfy long-term reliability requirements. For SiO₂, E_{BR} is about 10 MV/cm and E_{REL} may be in the range from about 2 MV/cm to about 4 MV/cm. Other dielectrics can each be characterized with particular values for E_{BR} and E_{REL}. As discussed above, the particular value of E_{REL} depends on the intended application, and E_{REL} may range from below 1 MeV/cm to just below E_{BR}.

In the event of a short circuit, shown as a dashed line in FIG. 2 in the load 152, a high internal power dissipation occurs which causes extremely rapid adiabatic heating of the power device 100 or 700. The generated heat does not have sufficient time to diffuse outward to any attached cooling apparatus (e.g. a heat sink) via normal thermal conduction before the device fails. The temperature rise ΔT that occurs inside the device during a short-circuit event of duration t_{sc} seconds can therefore be estimated by equation (3). The power dissipation is simply the current flowing in the device multiplied by the voltage across the drain and source terminals, i.e., P=I_{D}×V_{DS}.

In the MOS power device 700 shown in FIG. 9, the dielectric material 716 includes one or more layers of silicon dioxide, aluminum oxide, zirconium oxide, hafnium oxide, gallium oxide, lanthanum oxide, lanthanum aluminum oxide, beryllium oxide, or other suitable dielectric.

In the MOS power device 700 shown in FIG. 9, the material of the source, drain, and gate electrodes 712, 714, and 702, respectively, includes one or more of copper, silver, gold, carbon, graphite, nickel, titanium, aluminum, polysilicon, and graphene. According to one embodiment, the ohmic metal used on N-type regions such as the source and drain is nickel. The ohmic metal used on P-type regions such as the base is aluminum or nickel. It should be appreciated that these metals are used in SiC, while other metals may be used for other MOSFETs such as silicon MOSFETs and GaN MOSFETs. These metals are annealed at a high temperature, e.g., about 1000° C. —however, lower temperatures may be acceptable for various other semiconductor material, e.g., GaN—to form ohmic contacts, then they are covered with a thick (4-5 μm) conductive metal such as aluminum. A thin layer of titanium is typically used for adhesion, covered with a thicker layer of aluminum containing about 0.5% copper.

In the MOS power device 700 shown in FIG. 9, the drift semiconductor region 706 is in contact with the drain semiconductor region 704.

In the MOS power device 700 shown in FIG. 9, the base semiconductor region 708 is in contact with the drift semiconductor region 706.

In the MOS power device 700 shown in FIG. 9, the source semiconductor region 710 is in contact with the base semiconductor region 708.

In the MOS power device 700 shown in FIG. 9, the first conductivity type is N-type and the second conductivity type is P-type.

In the MOS power device 700 shown in FIG. 9, the first conductivity type is P-type and the second conductivity type is N-type.

In the MOS power device 700 shown in FIG. 9, the drain semiconductor region 704 has a dopant level higher than a dopant level of the drift semiconductor region 706.

In the MOS power device 700 shown in FIG. 9, the source semiconductor region 710 has a dopant level higher than a dopant level of the drift semiconductor region 706.

Referring to FIG. 10, a cross sectional view of a superjunction UMOSFET 800 is shown.

The MOS power device 800 includes a drain electrode 802 (identified as “Drain Contact”) in electrical contact with a drain semiconductor region 804 (shown as “N+ Drain”) of a first conductivity type (N type shown, however as explained below the first conductivity type can be P type while a second conductivity type can be N type). The material of the drain semiconductor region 804 can be doped silicon, doped silicon carbide, or other suitable semiconductor material. More is discussed below regarding the doping level. The MOS Power device 800 also includes alternating stacks, shown as “P Pillar”, “N Pillar”, and “P Pillar” of alternating conductivity types 805 and 806 of the second conductivity type and the first conductivity type (shown as “P Pillar Drift Region” and “N Pillar Drift Region”, however, as explained below the first conductivity type can be P type while a second conductivity type can be N type). The drift semiconductor regions 805 and 806 are coupled to the drain semiconductor region 804. The material of the drift semiconductor regions 805 and 806 can be doped silicon, doped silicon carbide, or other suitable semiconductor material. The MOS power device 800 further includes a base semiconductor region 808 of the second conductivity type (shown as “P Base”, however as explained below the second conductivity type can be N type while the first conductivity type can be P type). The base semiconductor region 808 is coupled to the drift semiconductor region 805 and isolated from the drain semiconductor region 804 by the pn junction at the interface between base region 808 and drift region 806. The material of the base semiconductor region 808 can be doped silicon, doped silicon carbide, or other suitable semiconductor material. The MOS power device 800 further includes a source semiconductor region 810 of the first conductivity type (shown as “N+ Source”, however as explained below the first conductivity type can be P type while the second conductivity type can be N type). The source semiconductor region 810 is coupled to the base semiconductor region 808 and isolated by the base semiconductor region 808 from the drift semiconductor regions 805 and 806. The material of the source semiconductor region 810 can be doped silicon, doped silicon carbide, or other suitable semiconductor material. The MOS power device 800 further includes a source electrode 812 (shown as “Source Contact”) that is coupled to the source semiconductor region 810, making electrical contact therewith. The MOS power device 800 further includes a gate electrode 814 (shown simply as “Gate”) that is provided adjacent at least a portion of but isolated from i) the base semiconductor region 808, ii) the source semiconductor region 810, and iii) the drift semiconductor region 806 by a dielectric material 816. The gate electrode 814 and the dielectric material 816 both are U-shaped, to be contrasted with the gate electrode 414 and the dielectric material 416 of the Superjunction DMOSFET shown in FIG. 4. The dielectric material 816 has a thickness between 1 nm and 30 nm (or between 1 nm and 25 nm, or between 1 nm and 20 nm, or between 1 nm and 15 nm, or between 1 nm and 10 nm, or between 1 and 5 nm) multiplied by a correction factor defined as a ratio of dielectric permittivity of the dielectric material and the permittivity of silicon dioxide. The drift semiconductor regions 805 and 806 have a sufficient thickness and doping to withstand greater than e.g., 100 V (this value depends on the semiconductor material—in silicon the drift region may only be designed to withstand greater than 20-30 V; in SiC, the drift region typically withstands more than 400-500 V; and GaN is above 50-100 V) between the drain electrode 802 and the source electrode 812 when substantially no current is flowing through the drain electrode 802. The MOS power device 800 further includes a semiconductor region 818 of the second conductivity type (shown as “P+ Source”, however as explained below the second conductivity type can be N type while the first conductivity type can be P type). The semiconductor region 818 is coupled to the base semiconductor region 808 and isolated by the base semiconductor region 808 from the drift semiconductor regions 805 and 806. The material of the semiconductor region 818 can be doped silicon, doped silicon carbide, or other suitable semiconductor material. The MOS power device 800 further includes a base contact 420 (shown as “Base Contact”) that is coupled to the semiconductor region 818, making electrical contact therewith.

If the gate-to-source voltage (V_{GS}) is above the threshold voltage V_{T}, a conducting channel (not shown, but known to a person having ordinary skill in the art) is induced along the surface of the semiconductor under the gate and the power device turns on. The gate insulator (i.e., the material 816) is a dielectric, and the most common dielectric is SiO₂. Other dielectric materials could also be used, for example Al₂O₃, Si₃N₄, HfO₂, ZrO₂, or layered combinations thereof.

Each dielectric material can be characterized in terms of two electric fields, the breakdown field (i.e., critical field) E_{BR} where the dielectric fails and no longer acts as an insulator, and the maximum reliable field E_{REL} beyond which the dielectric does not satisfy long-term reliability requirements. For SiO₂, E_{BR} is about 10 MV/cm and E_{REL} is about 4 MV/cm. Other dielectrics can each be characterized with particular values for E_{BR} and E_{REL}. As discussed above, the particular value of E_{REL} depends on the intended application, and E_{REL} may range from below 1 MeV/cm to just below E_{BR}.

In the event of a short circuit, shown as a dashed line in FIG. 2 in the load 152, a high internal power dissipation occurs which causes extremely rapid adiabatic heating of the power device 100 or 800. The generated heat does not have sufficient time to diffuse outward to any attached cooling apparatus (e.g. a heat sink) via normal thermal conduction before the device fails. The temperature rise ΔT that occurs inside the device during a short-circuit event of duration t_{sc} seconds can therefore be estimated using equation (3) provided above.

In the MOS power device 800 shown in FIG. 10, the dielectric material 816 includes one or more layers of silicon dioxide, aluminum oxide, zirconium oxide, hafnium oxide, gallium oxide, lanthanum oxide, lanthanum aluminum oxide, and beryllium oxide.

In the MOS power device shown in FIG. 10, the material of the source, drain, and gate electrodes 812, 814, and 802, respectively, includes one or more of copper, silver, gold, carbon, graphite, nickel, titanium, aluminum, polysilicon, and graphene. According to one embodiment, the ohmic metal used on N-type regions such as the source and drain is nickel. The ohmic metal used on P-type regions such as the base is aluminum or nickel. It should be appreciated that these metals are used in SiC, while other metals may be used for other MOSFETs such as silicon MOSFETs and GaN MOSFETs. These metals are annealed at a high temperature, e.g., about 1000° C.—however, lower temperatures may be acceptable for various other semiconductor material, e.g., GaN—to form ohmic contacts, then they are covered with a thick (4-5 μm) conductive metal such as aluminum. A thin layer of titanium is typically used for adhesion, covered with a thicker layer of aluminum containing about 0.5% copper.

In the MOS power device 800 shown in FIG. 10, the drift semiconductor regions 805 and 806 are in contact with the drain semiconductor region 804.

In the MOS power device 800 shown in FIG. 10, the base semiconductor region 808 is in contact with the drift semiconductor regions 805 and 806.

In the MOS power device 800 shown in FIG. 10, the source semiconductor region 810 is in contact with the base semiconductor region 808.

In the MOS power device 800 shown in FIG. 10, the first conductivity type is N-type and the second conductivity type is P-type.

In the MOS power device 800 shown in FIG. 10, the first conductivity type is P-type and the second conductivity type is N-type.

In the MOS power device 800 shown in FIG. 10, the drain semiconductor region 804 has a dopant level higher than a dopant level of the drift semiconductor regions 805 or 806.

In the MOS power device 800 shown in FIG. 10, the source semiconductor region 810 has a dopant level higher than a dopant level of the drift semiconductor regions 805 or 806.

FIG. 7 illustrates how the saturation current in a MOSFET can be reduced by simultaneously reducing the gate dielectric thickness t_{INS} and gate drive voltage (V_{G}−V_{T}) by the same factor κ. The charge per unit area induced in the inversion layer can be written

$${Q}_{n} = {C}_{ins} ( {V}_{G} - {V}_{T} ) = \frac{{ϵ}_{ins}}{{t}_{ins}} ( {V}_{G} - {V}_{T} ) \qquad ( 10 )$$

where ∈ᵢₙₛ is the dielectric permittivity of the gate dielectric. Reducing tᵢₙₛ and (V_{G}−V_{T}) by the same factor keeps the inversion charge Qₙ constant, and it follows that the electric field in the gate dielectric in the conducting state also remains constant by Gauss' Law.

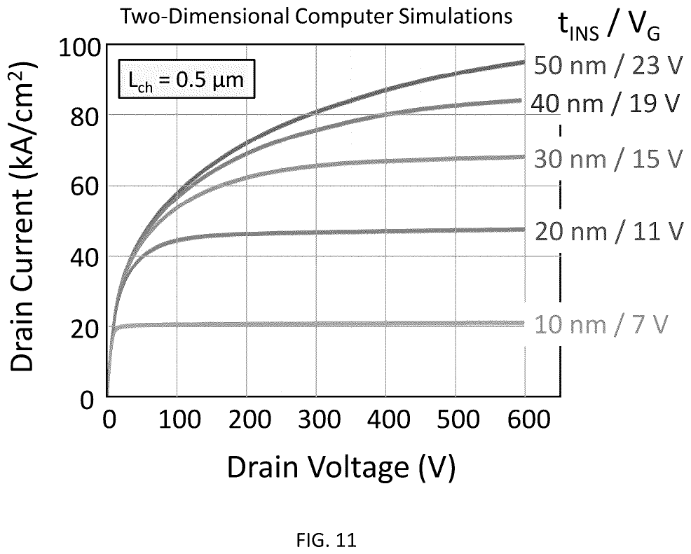

The data in FIG. 7 is calculated using the standard “long-channel” MOSFET equations contained in many textbooks. These equations assume the MOSFET channel length L_{CH} is sufficiently long that increasing the drain voltage in the saturation region does not affect the drain current. This can be seen, for example, in the 50 nm curve in FIG. 7 where the current remains constant for drain voltages above about 11 V. However, this does not accurately represent the behavior of modern short-channel power MOSFETs. FIG. 11 shows the current-voltage characteristics of a SiC power MOSFET with an SiO₂ gate dielectric and channel length of 0.5 μm calculated by two-dimensional numerical simulations. Unlike the simple analysis in FIG. 7, the current in FIG. 11 does not saturate for dielectric thicknesses in the range 40-50 nm, but instead continues to rise with increasing drain voltage. This is due to a phenomenon known as drain-induced barrier lowering (DIBL) that occurs when the channel is very short. In this situation the drain voltage can couple electrostatically to the potential barrier near the source end of the channel, reducing the barrier and allowing the current to increase. DIBL can have several undesirable consequences. First, it may lead to a reduction in threshold voltage V_{T}. Second, it may lead to an increased output conductance (increase of drain current as drain voltage is increased in the MOSFET current saturation region). Third, a reduction in short-circuit withstand time SCWT.

Drain-induced barrier lowering has been studied extensively in the development of silicon VLSI. Several papers have proposed procedures for scaling dimensions and dopings in a way that avoids DIBL, but none of these VLSI procedures can be applied to vertical power devices for two reasons: (i) unlike low-voltage MOSFETs used in VLSI, in a power device it is not possible to scale the applied drain voltage, since this voltage is constrained by the requirements of the application, and (ii) the VLSI MOSFETs have their drain terminals on the upper surface of the wafer, whereas a vertical power device has its drain terminal on the opposite (bottom) surface of the wafer, amounting to two completely different two-dimensional geometries.

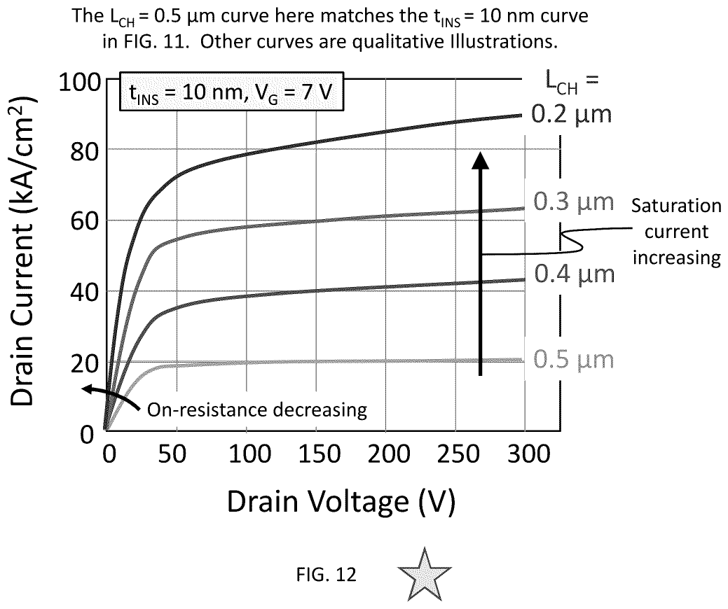

In the procedure we discussed up to this point for vertical power devices, the dielectric thickness and gate drive voltage were reduced the same factor k, keeping the lateral dimensions fixed. As seen by reference to the 10 nm curve in FIG. 11, this type of modified, partial scaling not only reduces the saturation current, but it can also eliminate the slope in the drain current in saturation (i.e. the DIBL). This suggests that, for a MOSFET with gate dielectric thickness of 10 nm, it should be possible to reduce the channel length below 0.5 μm while still keeping the saturation current below that of the original 50 nm curve. This is illustrated in FIG. 12, where reducing the channel length from 0.5 μm to 0.2 μm increases the saturation current (thereby reducing SCWT), but with the benefit of reduced on-resistance (steeper slope near the origin, corresponding to the normal operating point A in FIG. 6).

If we only reduce the dielectric thickness and gate voltage by κ, keeping channel length constant, this does not change the channel resistance R_{ch,sp} in (7) but it reduces the saturation current J_{d,sat} in (8) by κ, thereby increasing the SCWT by κ. But if we also reduce the channel length by a factor γ, the channel resistance R_{ch,sp} in (7) is reduced by γ while the saturation current in (8) is reduced by κ/γ. For example, if κ=4 and γ=2, the channel resistance is reduced by a factor of two and the saturation current is reduced by a factor of κ/γ which also equals two. Hence it now becomes possible to reduce both the channel resistance and the saturation current at the same time. Reducing the channel resistance reduces the on-state loss, while reducing the saturation current increases the SCWT.

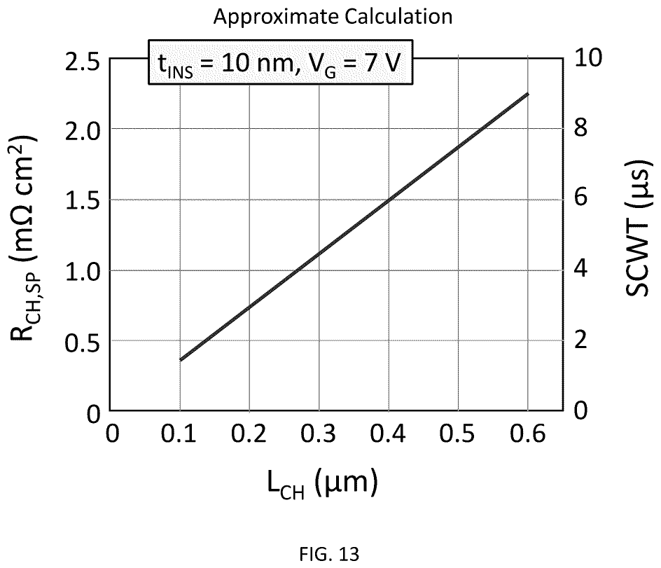

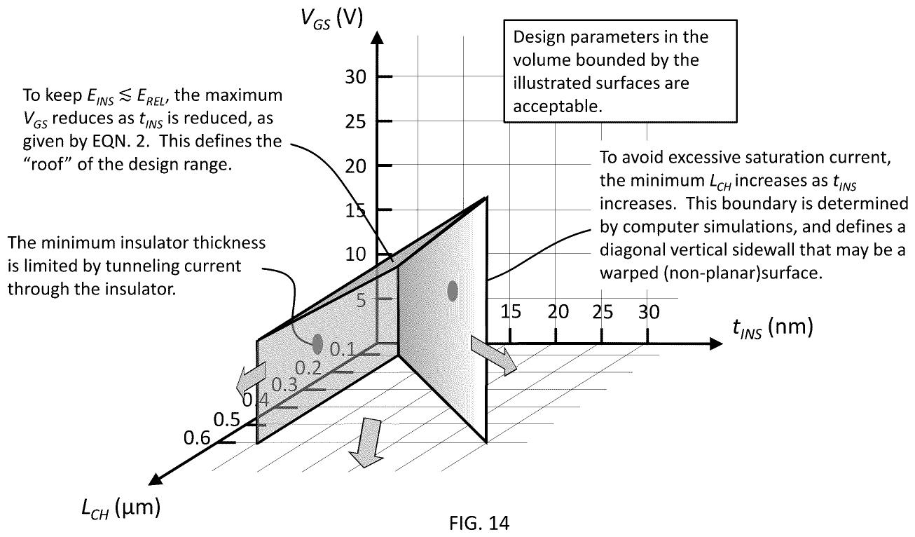

As shown by (7), channel resistance is proportional to channel length. Inserting (7) and (8) into (6) shows that SCWT is also proportional to channel length. The dependence of specific channel resistance R_{ch,sp} and SCWT t_{SC} on the insulator thickness t_{INS}, gate drive voltage (V_{G}−V_{T}), and channel length L_{CH} can be summarized in (11) and (12),

$$\begin{matrix}{R}_{ch , sp} = \frac{{L}_{ch} {t}_{ins} A}{{μ}_{ch} {W}_{ch} {ϵ}_{Iins} ( {V}_{G} - {V}_{T} )} & ( 11 ) \\ {t}_{SC} = \frac{8 ρ {C}_{P} Δ T {L}_{ch} {t}_{ins} A}{{μ}_{ch} {W}_{ch} {ϵ}_{ins} {E}_{CR} {( {V}_{G} - {V}_{T} )}^{2}} & ( 12 )\end{matrix}$$

where the symbols have the same meanings as defined earlier. These relationships are illustrated in FIG. 13, wherein it is shown that (i) in order for the insulator thickness tᵢₙₛ to be reduced, the gate drive voltage (V_{G}−V_{T}) must also be reduced to keep the oxide field ≤E_{REL}, and (ii) as the insulator thickness tᵢₙₛ is reduced, it should be possible to reduce the channel length L_{ch} up to the point where DIBL begins to present the above-enumerated challenges. Reducing the channel length directly reduces the specific channel resistance through (11). It should be understood that FIG. 14 is for illustrative purposes only, and our discussion is not constrained by the numerical values in this figure.

Given a specific SCWT requirement for the application, the designer can improve the performance of the MOSFET by reducing the channel length until reaching the minimum SCWT specified by the application. For example, if the application requires SCWT ≥4 μs, the designer can reduce channel length to 0.3 μm, thereby obtaining the minimum possible channel resistance for this SCWT and therefore the lowest possible on-state loss.

As stated above, the scaling rules previously published for low-voltage silicon MOSFETs cannot be directly applied to high-voltage SiC vertical power MOSFETs. Nevertheless, it is instructive to calculate the minimum channel length given by the silicon formulas using parameters for SiC power DMOSFETs. From the Brews reference, the minimum channel length can be estimated from

$${L}_{CH , MIN} [ μ m ] \approx 0.41 {( {x}_{J} [ μ m ] {t}_{ins} [ Å ] {\{ {W}_{S} + {W}_{D} \}}^{2} )}^{\frac{1}{3}} \qquad ( 13 )$$

where x_{J} is the source junction depth in microns,
tᵢₙₛ is the dielectric thickness in Angstroms, and
W_{S} and W_{D} are the source and drain depletion region widths in microns. For vertical power devices, W_{D} makes no sense because the drain junction is not located immediately at the end of the channel, so we set W_{D}=0. Using x_{J}=0.25 μm, tᵢₙₛ=10 nm (100 Å), and W_{S}=0.08 μm we calculate L_{CH,MIN} to be 0.22 μm. According to (7), reducing the channel length from 0.6-0.7 μm currently used in production of SiC MOSFETs would reduce the channel resistance by a factor of three.

Further referring to FIG. 14, a set of ranges for the three dimensions are provided in Table 1, below. In Table 1, the first column represents insulator thickness if the insulator is SiO₂. For SiO₂, the corresponding capacitance per unit area is provided in the second column. If other insulator material are used other than SiO₂, the values in the second column applies to those materials, which would represent different thicknesses based on the material choice. Thus the first and second columns are representative of one of the three axes shown in FIG. 14. The third column represents gate drive voltage which is also one of the three axes shown in FIG. 14. Finally, the fourth column in Table 1 is the channel length which is also one of the three axes shown in FIG. 14.

TABLE 1
Ranges of values of parameters shown in FIG. 14

| | Cᵢₙₛ range | (V_{g}-Vₜ) range | |
|---|---|---|---|
| tᵢₙₛ range | (applies to any | (for full-on | |
| (applies to SiO₂) | dielectric) | operation) | L_{ch} range |
| 40-50 nm | 6.90 × 10⁻⁸-8.63 × 10⁻⁸ F/cm² | 17-25 V | 0.4-0.6 μm |
| 30-40 nm | 8.63 × 10⁻⁸-1.15 × 10⁻⁷ F/cm² | 13-1 V | 0.3-0.5 μm |
| 20-30 nm | 1.15 × 10⁻⁷-1.73 × 10⁻⁷ F/cm² | 9-17 V | 0.2-0.4 μm |
| 10-20 nm | 1.73 × 10⁻⁷-3.45 × 10⁻⁷ F/cm² | 5-13 V | 0.1-0.3 μm |

As shown in FIG. 14, tᵢₙₛ is shown for SiO₂, which would be different for other insulator materials, as long as the thickness of those other materials follows the second column of Table 1. In order to keep the electric field in the insulator at or below a reliability field (E_{REL}), the maximum (V_{G}−V_{T}) reduces as tᵢₙₛ is reduced, thus defining the roof identified as 2. To avoid DIBL, discussed above, the minimum L_{ch} increases as tᵢₙₛ increases, thus defining the vertical wall identified as 1. The minimum R_{ch,sp} is obtained by the shortest channel that does not exhibit DIBL, and the highest (V_{G}−V_{T}) that keeps Eₙ≤E_{REL}. As a result, design parameters in the volume bounded by the vertical wall identified as 1 and the roof identified as 2 are acceptable.

It should be appreciated that in many places in the present disclosure the insulator is referred to as oxide or silicon oxide (SiO₂), but a number of other insulators can be used to accomplish the insulating functionality, as is known to a person having ordinary skill in the art.

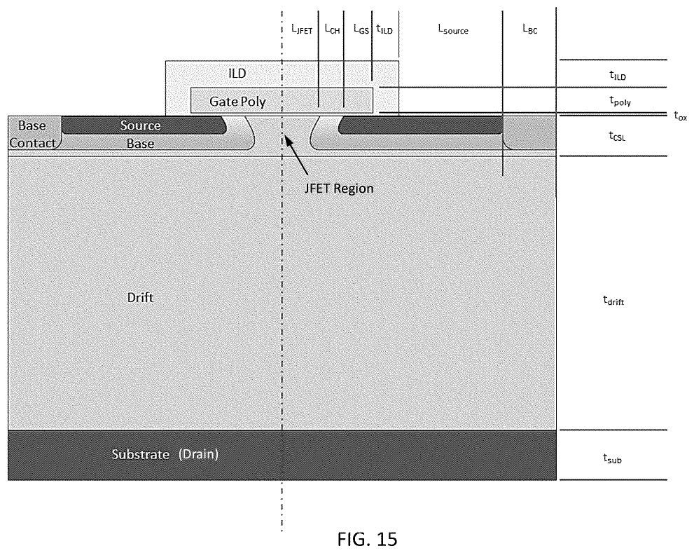

To confirm the accuracy of devices discussed herein, various simulations were carried out to demonstrate feasibility. Referring to FIG. 15, a schematic of a power MOSFET device, in particular a DMOSFET, is provided that is used for simulation depicting various structures, with dimensions provided only as a non-limiting example. The device provides a MOSFET structure with a gate poly disposed under an interlayer dielectric (ILD) over source region. Various structures, such as the JFET's length (L_{JFET}), channel length (L_{CH}), gate-to-source length (L_{GS}), ILD thickness (t_{ILD}), source length (L_{source}), base contact length (L_{CH}), poly thickness (t_{poly}), oxide thickness (tₒₓ), thickness of a current spreading layer (t_{csl}), thickness of the drift region, and thickness of the substrate (t_{sub}), which are all known to a person having ordinary skill in the art are shown in FIG. 15 along with example values shown in Table 2 for each such parameter.

TABLE 2
Example values for parameters shown in FIG. 15

| Simulation Parameters | | |
|---|---|---|
| L_{JFET} | 0.75 | μm |
| L_{CH} | 0.2-0.5 | μm |
| L_{GS} | 0.5 | μm |
| L_{source} | 2.0 | μm |
| L_{BC} | 1.0 | μm |
| t_{ILD} | 0.5 | μm |
| t_{poly} | 0.5 | μm |
| tₒₓ | 5-50 | nm |
| t_{CSL} | 0.75 | μm |
| t_{drift} | 5.2 | μm |

| | |
|---|---|
| t_{sub} | (not important to the simulation, |
| | but 1.0 μm was simulated) |
| N_{D, CSL} | 1 × 10¹⁷ cm⁻³ |
| N_{D, drift} | 2.5 × 10¹⁶ cm⁻³ |
| N_{D, sub} | 1 × 10¹⁹ cm⁻³ |
| N_{D, gate} | 1 × 10²⁰ cm⁻³ |

The gate oxide is SiO₂.

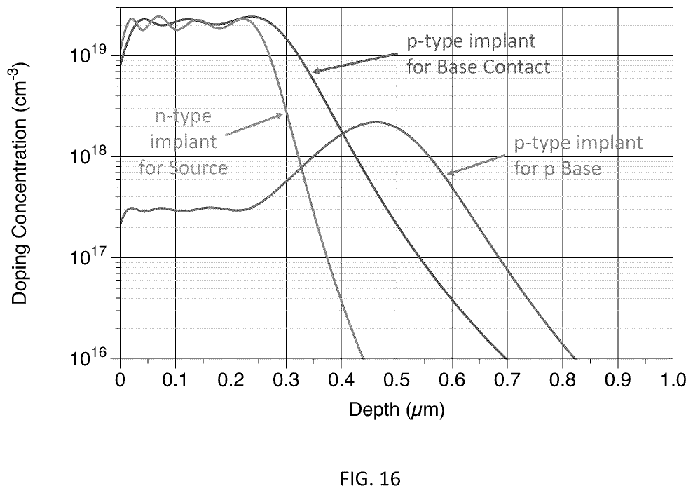

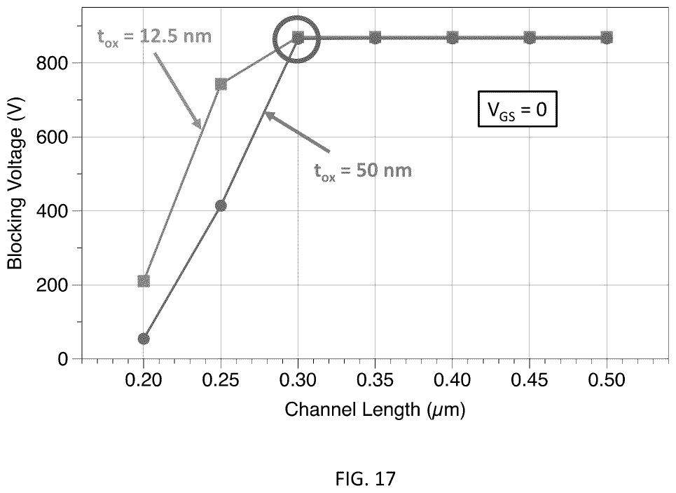

Referring to FIG. 16, a doping profile (i.e., doping concentration in cm⁻³ vs. depth in m) is provided for the different regions of the structure depicted in FIG. 15. This doping profile is an example of the profiles typically used in SiC power MOSFETs, as is known to a person having ordinary skill in the art. FIGS. 17-24 are based on the doping profile shown in FIG. 16 and the structure depicted in FIG. 15 as well as the parameters listed in Table 2. However, it should be appreciated that the doping profile depicted in FIG. 16 and the parameter provided in Table 2 are non-limiting examples and other doping profiles and device parameters can be utilized. Referring to FIG. 17, a graph of blocking voltage in V vs. channel length for the doping profile of FIG. 16 is provided. The blocking voltage represents an important parameter when the device is off. The channel length was varied from about 0.2 μm to about 0.5 μm. As it is clear from FIG. 17, the blocking voltage degrades quickly when the channel length has reduced to below 0.3 μm in this example. Thus, from FIG. 17, it can be deduced for the parameters shown in Table 2 and the doping profile shown in FIG. 16, the minimum channel length is about 0.3 μm. Two graphs are shown in FIG. 17, one for tₒₓ of about 50 nm and one for tₒₓ of about 12.5 nm. Interestingly, not only the thinner oxide provides a better short circuit withstand time, the degradation of the blocking voltage is also slightly less severe for the thinner oxide trial. Regardless, for both sets of graph, the minimum channel length is about 0.3 μm before the blocking voltage begins to drastically degrade. The degradation in blocking voltage for channel lengths below about 0.3 μm is due to punchthrough of the drain depletion region through the portion of the p base between the JFET region and the source as the channel length is reduced, as would be appreciated by a person of ordinary skill in the art.

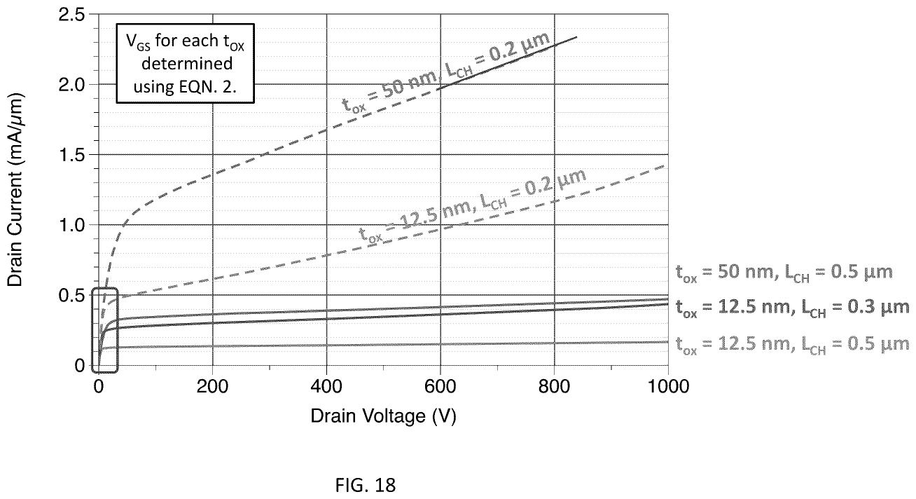

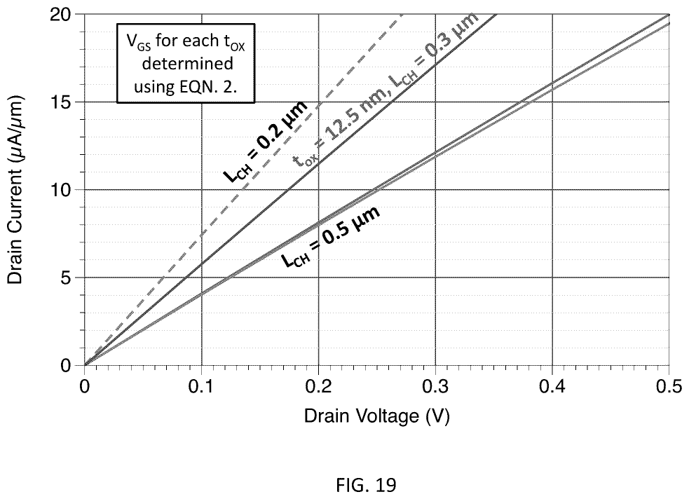

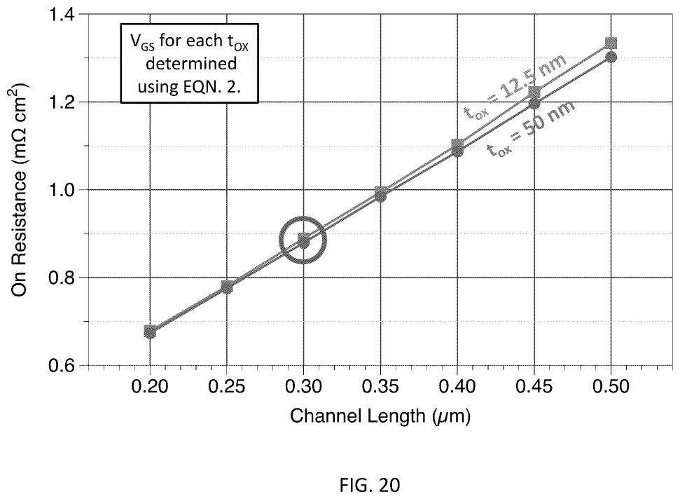

Referring to FIG. 18, the device in the on state is shown with respect to the drain current in mA/μm (i.e., current per unit width of the MOSFET, where width is measured in μm) vs. drain voltage in V. In FIGS. 18-24, wherever the oxide thickness tₒₓ is specified, it should be remembered that the on-state gate-to-source voltage V_{GS} for that oxide thickness is determined using EQ. (2). Five graphs are shown for L_{CH} of 0.5 μm, 0.3 μm, and 0.2 μm and for tₒₓ of 12.5 nm and 50 nm. In the saturation region, the device behaves properly (i.e., with increasing drain voltage beyond the linear region, the drain current settles into a constant or near-constant level for all the channel lengths greater than about 0.3 μm; however, for channel length of about 0.2 μm, regardless of which of the two oxide thickness (i.e., 12.5 nm or 50 nm), the saturation current improperly increases with increasing drain voltage. This figure again emphasizes that channel lengths of a minimum of about 0.3 μm provide appropriate behavior, but channel lengths below 0.3 μm (e.g., 0.2 μm) provide improper behavior. Referring to FIG. 19, the linear region near the origin of FIG. 18 is shown in greater detail. In line with FIG. 19, an on-resistance in mΩ-cm² vs. channel length in μm is shown for various channel lengths in FIG. 20. As seen by the slope of the curves in FIG. 19, the on resistance is beneficially decreased with decreasing channel length. There is very little difference in terms of on resistance from the perspective of oxide thickness as the two lines representing the linear relationship between channel length and on resistance are almost coincident. This relationship makes sense since the gate-to-source voltage is reduced along with oxide thickness according to EQ. (2) in order to keep the oxide field in the on-state at or below the maximum field for long-term reliability, E_{REL}.

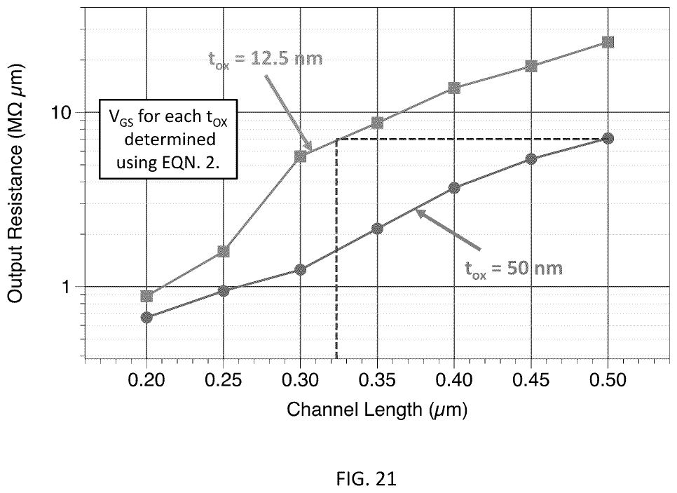

Referring to FIG. 21, output resistance in M2-μm is provided against channel length in μm in a logarithmic plot for the two oxide thicknesses (i.e., 12.5 nm and 50 nm). Output resistance is the reciprocal of the increase in drain current (I_{d}) per unit increase in drain-to-source voltage (V_{ds}), evaluated well into the saturation region (e.g., between V_{ds}=600 V and V_{ds}=1000 V in FIG. 18). The dashed lines in FIG. 21 illustrate how such a plot might be used by a person of ordinary skill in the art. Suppose a designer wishes to find the shortest channel length for a 12.5 nm oxide thickness that gives an output resistance as least as large as that of a 50 nm oxide at a channel length of 0.5 μm. The designer could extend a horizontal line to the left from the tₒₓ=50 nm line at a channel length of 0.5 μm. The point where this line intersects the tₒₓ=12.5 nm defines the minimum channel length for this oxide thickness that would have an output resistance at least as large as that of a 50 nm oxide at a channel length of 0.5 μm (about 0.324 μm in this example).

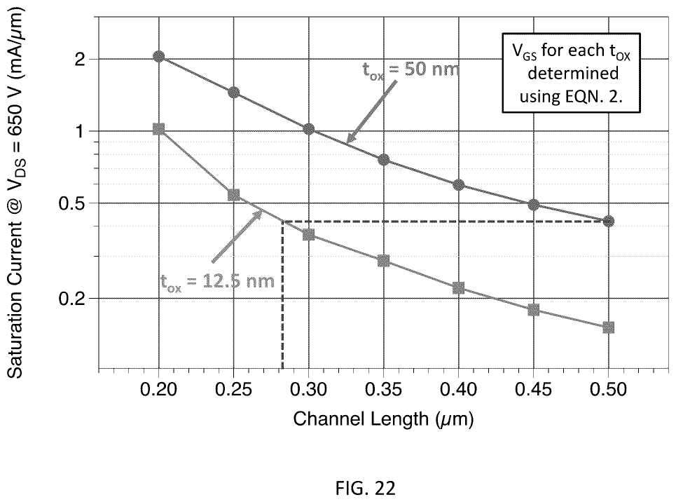

Referring back to the saturation current, a more detailed impact on the saturation current in mA/μm at V_{DS}=650 V is provided in FIG. 22 for various channel lengths in μm. This figure demonstrates that if one wants to keep the saturation current of the 12.5 nm oxide device to be no greater than that of the standard oxide device with a channel length of 0.5 μm, then one can't reduce the channel length below 0.28 μm, as is illustrated by the dashed lines in the figure.

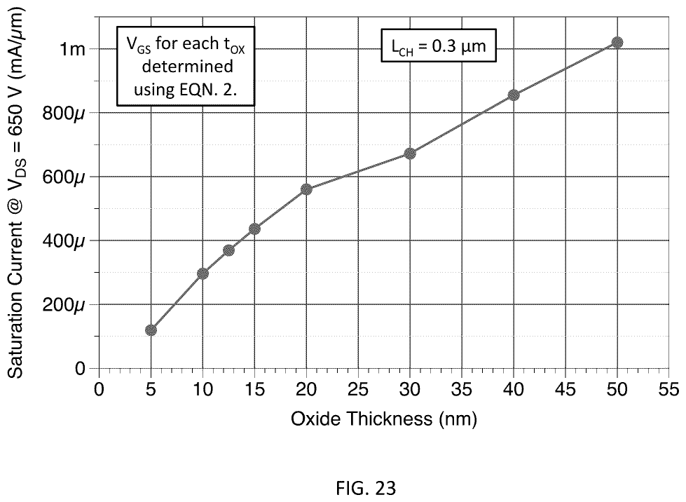

Referring to FIG. 23, a graph of saturation current in mA/μm at V_{DS}=650 V is provided vs. oxide thickness in nm for one instance of channel length of 0.3 μm, showing a decrease in saturation current with decreasing oxide thickness. This figure demonstrates how the saturation current at a full-on gate voltage is reduced when the oxide thickness is reduced. The reduction in saturation current occurs because the gate-to-source voltage V_{GS} is being reduced along with oxide thickness according to EQ. (2). Reducing the saturation current increases the short-circuit withstand time.

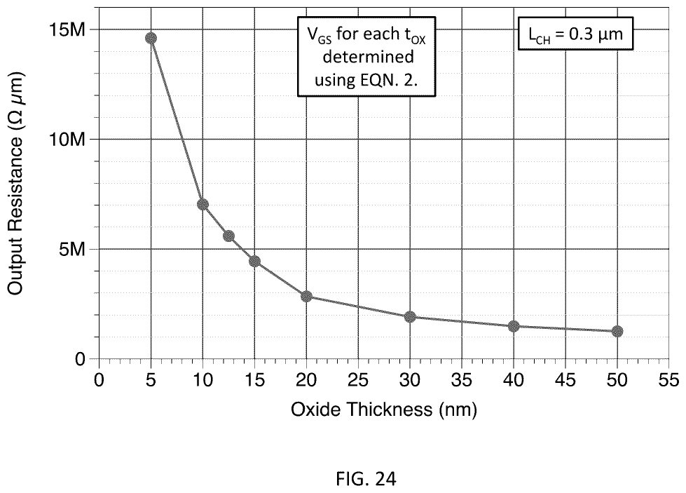

Referring to FIG. 24, a graph of output resistance in Ω-μm is provided vs. oxide thickness in nm for one instance of channel length of 0.3 μm. As in the previous figure, as oxide thickness is reduced, the gate-to-source voltage V_{GS} is also reduced according to EQ. (2).

Based on the above-described simulations, a series of specific ranges of channel lengths and corresponding ranges of oxide thicknesses are identified. Since there is no operational penalty of using a thinner oxide, the lower limit of each oxide thickness range is 5 nm, only limited by tunneling. Hence, table 3 provided below provides example channel lengths and the corresponding oxide thicknesses. This table is also further depicted in FIG. 14 which is provided for demonstration-purposes only.

TABLE 3
Example channel length and a corresponding oxide thickness
therefor established for the device shown in FIG. 15,
the doping profile provided in FIG. 16, and the parameters
provided in Table 2 for 4H-SiC semiconductor and a gate
dielectric of SiO₂.

| Channel Length | Oxide Thickness |
|---|---|
| 0.6 μm-0.5 μm | 5 nm-30 nm |
| 0.5 μm-0.4 μm | 5 nm-25 nm |
| 0.4 μm-0.3 μm | 5 nm-20 nm |
| 0.3 μm-0.2 μm | 5 nm-15 nm |
| 0.2 μm-0.1 μm | 5 nm-10 nm |

Those having ordinary skill in the art will recognize that numerous modifications can be made to the specific implementations described above. The implementations should not be limited to the particular limitations described. Other implementations may be possible.

1. A metal oxide semiconductor (MOS)-based power device in 4H-SiC semiconductor, comprising:
a semiconductor region;
a drain electrode and a source electrode;
a gate electrode separated from the semiconductor region by silicon dioxide as a dielectric material, wherein a load current passing through the drain and source electrodes is controlled by an electric field induced by the gate electrode into the semiconductor region thereby forming a conductive channel;
where the channel length has a range of between about 0.6 μm and about 0.5 μm, the silicon dioxide has a corresponding thickness range of between about 5 nm to about 30 nm,
where the channel length has a range of between about 0.5 μm and about 0.4 μm, the silicon dioxide has a corresponding thickness range of between about 5 nm to about 25 nm,
where the channel length has a range of between about 0.4 μm and about 0.3 μm, the silicon dioxide has a corresponding thickness range of between about 5 nm to about 20 nm,
where the channel length has a range of between about 0.3 μm and about 0.2 μm, the silicon dioxide has a corresponding thickness range of between about 5 nm to about 15 nm and
wherein the device is configured to withstand greater than 100 V between the source and the drain electrodes while carrying the load current.

2. The MOS-based power device of claim 1, wherein material of the drain, source, and gate electrodes comprises one or more of copper, silver, gold, carbon, graphite, nickel, titanium, aluminum, polysilicon, and graphene.

3. The MOS-based power device of claim 1, wherein the semiconductor region comprises an N-type conductivity type and a P-type conductivity type.

4. The MOS-based power device of claim 1, wherein the semiconductor region comprises a first semiconductor region, a second semiconductor region, and a third semiconductor region.

5. The MOS-based power device of claim 4, wherein the first semiconductor region has a dopant level higher than a dopant level of the second semiconductor region.

6. The MOS-based power device of claim 5, wherein the third semiconductor region has a dopant level higher than a dopant level of the second semiconductor region.

7. The MOS-based power device of claim 1, wherein the electric field induced by the gate electrode is based on application of a gate-to-source voltage (V_{GS}) established based on the thickness of the dielectric material.

8. The MOS-based power device of claim 7, wherein V_{GS} is expressed as a function of the thickness of the dielectric material based on:
Eᵢₙₛ=(V_{GS}−φ_{GS}−2ψ_{F})/tᵢₙₛ
Eᵢₙₛ is the electric field induced by the gate electrode,
φ_{GS} is a work function difference between the gate material and the semiconductor in the channel region in volts,
ψ_{F} is the bulk Fermi potential of the semiconductor material in the channel region (determined by its doping) in volts, and
tᵢₙₛ is the thickness of the dielectric material between the gate and the semiconductor in centimeters.

9. The MOS-based power device of claim 1, wherein capacitance per unit area of the dielectric material is greater than about 6.90×10⁻⁸ F/cm² and the channel length has a range of between about 0.6 μm and about 0.5 μm.

10. The MOS-based power device of claim 1, wherein capacitance per unit area of the dielectric material is greater than about 8.63×10⁻⁸ F/cm² and the channel length has a range of between about 0.5 μm and about 0.4 μm.

11. The MOS-based power device of claim 1, wherein capacitance per unit area of the dielectric material is greater than about 1.15×10⁻⁷ F/cm² and the channel length has a range of between about 0.4 μm and about 0.3 μm.

12. The MOS-based power device of claim 1, wherein the device is a planar MOS field effect transistor (MOSFET).

13. The MOS-based power device of claim 12, wherein the planar MOSFET is a DMOSFET.

14. The MOS-based power device of claim 1, wherein the device is a trench MOSFET.

15. The MOS-based power device of claim 1, wherein the device is a lateral MOSFET.

16. The MOS-based power device of claim 1, wherein the device is a planar superjunction MOSFET.

17. The MOS-based power device of claim 1, wherein the device is a trench superjunction MOSFET.

18. The MOS-based power device of claim 1, wherein the device is a planar insulated-gate bipolar transistor.

19. The MOS-based power device of claim 1, wherein the device is a trench insulated-gate bipolar transistor

20. The MOS-based power device of claim 1, wherein the device is a planar MOS-controlled thyristor.

21. The MOS-based power device of claim 1, wherein the device is a trench MOS-controlled thyristor.
